(19) United States
(12) Patent Application Publication
(10) Pub. No.: US 2026/0271496 A1
(43) Pub. Date: Sep. 10, 2026

(54) LIGHT-EMITTING ELEMENT AND DISPLAY DEVICE

(71) Applicant: Sharp Display Technology Corporation, Kamayama City, MIe (JP)

(72) Inventor: YUSUKE SAKAKIBARA, Sakai City, Osaka (JP)

(21) Appl. No.: 19/121,538

(22) PCT Filed: Oct. 16, 2023
(86) PCT No.: PCT/JP2023/037330

§ 371 Date: Apr. 16, 2025

(30) Foreign Application Priority Data
Oct. 18, 2022 (WO) PCT/JP2022/038711

(51) Int. Cl. H10K 50/115

(52) U.S. Cl. CPC H10K 50/115

(57) ABSTRACT

An emission layer (Em) provided in a light-emitting element according to the present disclosure includes a first quantum dot and a second quantum dot separated from each other. The first quantum dot includes a first core, a shell being in contact with the first core, and a first layer formed outside the shell and formed from a first material. The second quantum dot includes a second core, and a second layer being in contact with the second core and formed from a second material.

### TECHNICAL FIELD

The present disclosure relates to a light-emitting element and a display device.

### BACKGROUND ART

Patent Literature 1 discloses a configuration in which two kinds of quantum dots having different ligands are mixed to improve a contact angle, and discloses an example in which the shell thicknesses of the two kinds of quantum dots are different.

### CITATION LIST

### Patent Literature

Patent Literature 1: CN112342013

### SUMMARY

### Technical Problem

The example in Patent Literature 1 uses a single material for the shells of the two kinds of quantum dots. Thus, lattice strain becomes large along with shell thickness increase, unfortunately reducing emission efficiency.

### Solution to Problem

A light-emitting element according to one aspect of the present disclosure is provided with the following: an anode; a cathode; and an emission layer positioned between the anode and the cathode. The emission layer includes a first quantum dot and a second quantum dot separated from each other. The first quantum dot includes a first core, a shell being in contact with the first core, and a first layer formed outside the shell and formed from a first material. The second quantum dot includes a second core, and a second layer being in contact with the second core and formed from a second material.

A display device according to one aspect of the present disclosure includes the light-emitting element according to the aspect of the present disclosure.

### Advantageous Effect of Disclosure

The foregoing light-emitting element can improve emission stability in a low-voltage region, and emission efficiency in a high-voltage region.

### BRIEF DESCRIPTION OF DRAWINGS

FIG. 1 is a cross-sectional view of an example of the configuration of a light-emitting element according to one embodiment of the present disclosure.

FIG. 2 is a cross-sectional view of an example of the configuration of an emission layer illustrated in FIG. 1.

FIG. 3 illustrates an example of the energy band structure of first and second quantum dots included in the emission layer illustrated in FIG. 2 with an organic ligand member included therein.

FIG. 4 is a cross-sectional view of another example of the configuration of the emission layer illustrated in FIG. 1.

FIG. 5 illustrates an example of the energy band structure of the first and second quantum dots included in the emission layer illustrated in FIG. 4 with an inorganic matrix member included therein, and of the nearby inorganic matrix member.

FIG. 6 is a schematic diagram illustrating an example of a quantum-dots-dispersed solution for the emission layer illustrated in FIG. 2.

FIG. 7 is a cross-sectional view of an example of the configuration of the emission layer in the light-emitting element according to one embodiment of the present disclosure.

FIG. 8 is a cross-sectional view of another example of the configuration of the emission layer in the light-emitting element according to the embodiment of the present disclosure.

FIG. 9 is a cross-sectional view of an example of the configuration of the emission layer in the light-emitting element according to one embodiment of the present disclosure.

FIG. 10 is a cross-sectional view of another example of the configuration of the emission layer in the light-emitting element according to the embodiment of the present disclosure.

FIG. 11 is a cross-sectional view of an example of the configuration of the emission layer in the light-emitting element according to one embodiment of the present disclosure.

FIG. 12 is a cross-sectional view of another example of the configuration of the emission layer in the light-emitting element according to the embodiment of the present disclosure.

FIG. 13 illustrates an example of the energy band structure of the first and second quantum dots included in the emission layer illustrated in FIG. 11 with an organic ligand member included therein.

FIG. 14 illustrates an example of the energy band structure of the first and second quantum dots included in the emission layer illustrated in FIG. 12 with an inorganic matrix member included therein, and of the nearby inorganic matrix member.

FIG. 15 is a cross-sectional view of an example of the configuration of the emission layer in the light-emitting element according to one embodiment of the present disclosure.

FIG. 16 is a cross-sectional view of another example of the configuration of the emission layer in the light-emitting element according to the embodiment of the present disclosure.

FIG. 17 is a cross-sectional view of an example of the configuration of the emission layer in the light-emitting element according to one embodiment of the present disclosure.

FIG. 18 is a cross-sectional view of another example of the configuration of the emission layer in the light-emitting element according to the embodiment of the present disclosure.

FIG. 19 illustrates an example of the energy band structure of the first and second quantum dots included in the emission layer illustrated in FIG. 17 with an organic ligand member included therein.

FIG. 20 illustrates an example of the energy band structure of the first and second quantum dots included in the emission layer illustrated in FIG. 18 with an inorganic matrix member included therein, and of the nearby inorganic matrix member.

FIG. 21 is a cross-sectional view of an example of the configuration of the emission layer in the light-emitting element according to one embodiment of the present disclosure.

FIG. 22 is a cross-sectional view of another example of the configuration of the emission layer in the light-emitting element according to the embodiment of the present disclosure.

FIG. 23 illustrates an example of the energy band structure of the first and second quantum dots included in the emission layer illustrated in FIG. 21 with an organic ligand member included therein.

FIG. 24 illustrates an example of the energy band structure of the first and second quantum dots included in the emission layer illustrated in FIG. 22 with an inorganic matrix member included therein, and of the nearby inorganic matrix member.

FIG. 25 is a cross-sectional view of an example of the configuration of the light-emitting element according to one embodiment of the present disclosure.

FIG. 26 is a schematic diagram illustrating an example of a region between quantum dots illustrated in FIG. 25.

FIG. 27 is a cross-sectional view of an example of the configuration of the emission layer illustrated in FIG. 25.

FIG. 28 illustrates an example of the energy band structure of the first and second quantum dots illustrated in FIG. 27, and of the nearby inorganic matrix member.

FIG. 29A is a graph showing the particle diameter distribution of the quantum dots in the emission layer.

FIG. 29B is a graph showing the particle diameter distribution of the quantum dots in the emission layer.

FIG. 30 is a schematic diagram illustrating an example of a quantum-dots-dispersed solution for the emission layer illustrated in FIG. 25.

FIG. 31 is a flowchart showing an example of a method for manufacturing the light-emitting element illustrated in FIG. 25.

FIG. 32 is a schematic circuit diagram of the light-emitting element according to an example of the present disclosure.

FIG. 33 is a graph showing the relationship between the driving voltages [V] of the first and second quantum dots illustrated in FIG. 32, and current density [mA/cm²].

FIG. 34 is a graph showing the relationship between the driving voltages [V] of the first and second quantum dots illustrated in FIG. 32, and luminance [cd/m²].

FIG. 35 is a graph showing the relationship between the current densities [mA/cm²] of the first and second quantum dots and light-emitting element illustrated in FIG. 32, and luminance [cd/m²].

FIG. 36 is a schematic circuit diagram of the light-emitting element according to an example of the present disclosure.

FIG. 37 is a graph showing the relationship between the current densities [mA/cm²] of the first and second quantum dots and light-emitting element illustrated in FIG. 36, and luminance [cd/m²].

FIG. 38 is a cross-sectional view of an example of the configuration of the emission layer according to one embodiment of the present disclosure.

FIG. 39 is a cross-sectional view of an example of the configuration of the emission layer according to one embodiment of the present disclosure.

FIG. 40 illustrates an example of the energy band structure of the first and second quantum dots illustrated in FIG. 39, and of the nearby inorganic matrix member.

FIG. 41 is a cross-sectional view of an example of the configuration of the emission layer according to one embodiment of the present disclosure.

FIG. 42 is a cross-sectional view of an example of the configuration of the emission layer according to one embodiment of the present disclosure.

FIG. 43 illustrates an example of the energy band structure of the first and second quantum dots illustrated in FIG. 42, and of the nearby inorganic matrix member.

FIG. 44 is a cross-sectional view of a modification of the configuration of the emission layer according to the embodiment of the present disclosure.

FIG. 45 is a cross-sectional view of a modification of the configuration of the emission layer according to the embodiment of the present disclosure.

FIG. 46 illustrates an example of the energy band structure of the first and second quantum dots illustrated in FIG. 45, of third and fourth quantum dots illustrated in FIG. 25, and of the nearby inorganic matrix member.

FIG. 47 is a plan view of an example of the configuration of a display device according to one embodiment of the present disclosure.

FIG. 48 is a cross-sectional view of an example of the configuration of the display device according to the embodiment of the present disclosure.

### DESCRIPTION OF EMBODIMENTS

### First Embodiment

### Configuration of Light-Emitting Element

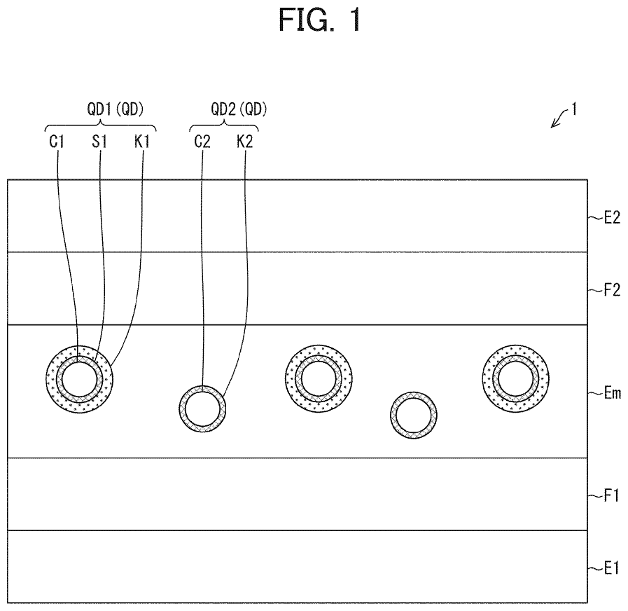

FIG. 1 is a cross-sectional view of an example of the configuration of a light-emitting element according to one embodiment of the present disclosure. As illustrated in FIG. 1, a light-emitting element 1 is provided with an anode E1 and a cathode E2 facing each other, and an emission layer Em positioned between the anode E1 and the cathode E2. The emission layer Em includes a first quantum dot QD1 and a second quantum dot QD2 separated from each other (that is, they are not in contact together). The first quantum dot QD1 includes a first core C1, a shell S1 being in contact with the first core C1, and a first layer K1 formed outside the shell S1 and formed from a first material. The second quantum dot QD2 includes a second core C2, and a second layer K2 being in contact with the second core C2 and formed from a second material.

In this way, providing the first quantum dot QD1 and second quantum dot QD2 with different configurations around their cores enables one of the first quantum dot QD1 and second quantum dot QD2 to have a property in which its quantum confinement effect is low, thus exhibiting excellent emission efficiency in a low-current region, and enables the other to have a property in which its quantum confinement effect is high, thus exhibiting excellent emission efficiency in a high-current region. For example, providing an organic ligand member Rx around the first quantum dot QD1 and second quantum dot QD2 enables the first quantum dot QD1 to have a property in which its quantum confinement effect is higher than that of the second quantum dot QD2, thus exhibiting more excellent emission efficiency in a high-current region than the second quantum dot QD2, and enables the second quantum dot QD2 to have a property in which its quantum confinement effect is lower than that of the first quantum dot QD1, thus exhibiting more excellent emission efficiency in a low-current region than the first quantum dot QD1. Further, providing an inorganic matrix member around the first quantum dot QD1 and second quantum dot QD2 enables the first quantum dot QD1 to have a property in which its quantum confinement effect is lower than that of the second quantum dot QD2, thus exhibiting more excellent emission efficiency in a low-current region than the second quantum dot QD2, and enables the second quantum dot QD2 to have a property in which its quantum confinement effect is higher than that of the first quantum dot QD1, thus exhibiting more excellent emission efficiency in a high-current region than the first quantum dot QD1. Consequently, the emission stability in a low-voltage region and the emission efficiency in a high-voltage region can be improved in the emission layer Em including the first quantum dot QD1 and second quantum dot QD2.

The maximum outer diameter of the first quantum dot QD1 according to one embodiment of the present disclosure is larger than the maximum outer diameter of the second quantum dot QD2. A quantum dot's outer diameter in the present disclosure means the distance between two points where a straight line passing through the quantum dot's core center crosses the outer surface of the quantum dot's outermost layer. The first quantum dot QD1 with a large maximum outer diameter enables the first layer K1 to be provided at no expense of the thickness of the shell S1. The thickness of the second layer K2 may be equal to the thickness of the shell S1.

In the present disclosure, the thickness of a shell or layer that constitutes a quantum dot QD may be determined by observing the cross section of the emission layer Em with a scanning electron microscope (SEM). In the present disclosure, the expression “a thickness is equal to another thickness” encompasses not only a case where the two thicknesses are exactly the same, but also a case where the difference between the two thicknesses is sufficiently small; for instance, when the difference between the two thicknesses measures 0.3 [nm] or less, the two thickness can be regarded as being equal.

The material of the shell S1 and the first material, which is contained in the first layer K1, are different. The material of the shell S1 and the first material may be selected in such a manner that the lattice constant of the material of the shell S1 falls between the lattice constant of the material of the first core C1 and the lattice constant of the first material. This reduces a mismatch in lattice constant between the first core C1, the shell S1, and the first layer K1, thereby enabling reduction of lattice defects in the first quantum dot QD1. This lattice defect reduction can improve the emission efficiency of the first quantum dot QD1.

The material of the shell S1 may be identical to the second material, which is contained in the second layer K2. This can partly commonize the manufacturing processes of the first quantum dot QD1 and second quantum dot QD2, thereby reducing the manufacturing costs for the light-emitting element 1. It is noted that the expression “materials are identical” in the present disclosure does not have to encompass a composition match between the materials of respective target components.

The material of the first core C1 and the material of the second core C2 may be identical. This can partly commonize the manufacturing processes of the first quantum dot QD1 and second quantum dot QD2, thereby reducing the manufacturing costs for the light-emitting element 1. Furthermore, the diameters of the first core C1 and second core C2 may be equal. The first quantum dot QD1 and the second quantum dot QD2 can consequently emit light of the same color. The core diameter can be defined as the diameter of a circle having the same area as the core's cross-sectional area in cross-sectional view.

### Organic Ligand Member and Quantum Confinement Effect

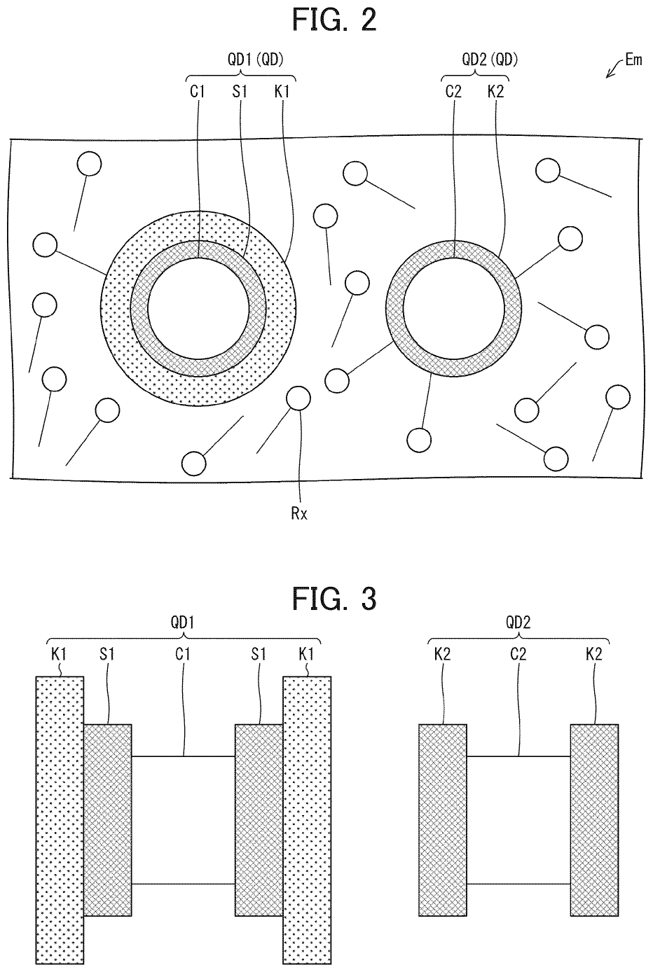

FIG. 2 is a cross-sectional view of an example of the configuration of the emission layer illustrated in FIG. 1. As illustrated in FIG. 2, the emission layer Em may further include the organic ligand member Rx positioned between the first quantum dot QD1 and the second quantum dot QD2. The organic ligand member Rx may include an organic ligand member being in contact with the first layer K1, and an organic ligand member being in contact with the second layer K2. The light-emitting element 1, which includes the organic ligand member Rx positioned between the first quantum dot QD1 and the second quantum dot QD2, can enhance the emission efficiency of the second quantum dot QD2 with a small particle diameter and can prevent deterioration in the second quantum dot QD2. The light-emitting element 1, which includes the second quantum dot QD2 with a small particle diameter, can improve the emission stability in a low-voltage region.

In the present disclosure, a ligand member means molecules and ions that can bind to a quantum dot. More specifically, a ligand member includes not only molecules and ions that are currently binding to a quantum dot, but also molecules and ions that can bind to a quantum dot but are not binding to it. The organic ligand member Rx can be appropriately selected from among materials that are typically used in this field; example include, but not limited to, alkylthiol, alkylamine, alkylcarboxylic acid, and alkylated phosphorus.

In the example illustrated in FIG. 2, the material of the first core C1 and the material of the second core C2 may be identical. In addition, the core diameters of the first core C1 and second core C2 may be equal; in addition, the material of the shell S1 may be identical to the second material, which is contained in the second layer K2; in addition, the thickness of the shell S1 may be equal to the thickness of the second layer K2.

FIG. 3 illustrates an example of the energy band structure of the first and second quantum dots included in the emission layer illustrated in FIG. 2 with an organic ligand member included therein. In the present disclosure, a band gap means a level difference between the upper end of a valence band (VB) and the lower end of a conduction band (CV). As shown in FIG. 3, the material of the shell S1 has a larger band gap than the material of the first core C1. In addition, the first material, which is contained in the first layer K1, has a larger band gap than the material of the shell S1. Thus, excitons generated in the first core C1 and the second core C2 are confined based on quantum effect. Specifically, the excitons in the first core C1 need to pass through an energy barrier formed by the shell S1 and first layer K1, by tunnel effect in order to go out of the first quantum dot QD1. In addition, the excitons in the second core C2 need to pass through an energy barrier formed by the second layer K2, by tunnel effect in order to go out of the second quantum dot QD2. Thus, the quantum confinement effect on the excitons in the first core C1 is stronger than the quantum confinement effect on the excitons in the second core C2. The higher the quantum confinement effect is, the higher the upper limit of emission efficiency becomes.

Further, due to the first layer K1, electric-charge injection into the first quantum dot QD1 is more difficult than electric-charge injection into the second quantum dot QD2. Experimentally, the turn-on voltage of the first quantum dot QD1 is larger than the turn-on voltage of the second quantum dot QD2. Hence, the light-emitting element 1 can emit light at a voltage equal to or larger than the turn-on voltage of the second quantum dot QD2, and can improve the emission stability in a low-voltage region. The light-emitting element 1 can also improve the emission efficiency in a high-voltage region, because the first quantum dot QD1 emits light at a voltage equal to or larger than the turn-on voltage of the first quantum dot QD1.

Table 1 shows some example combinations of organic ligand members in a case where an emission layer of a material that can be used in the light-emitting element according to one embodiment of the present disclosure includes organic ligand members. As shown in Table 1, the first material, which is contained in the first layer K1, may be an insulating material, such as silicon oxide. The first material may be a semiconductor material, such as zinc sulfide, zinc selenide sulfide, or zinc selenide.

TABLE 1

| First Core | Shell | |
|---|---|---|
| Second Core | Second Layer | First Layer |
| InP | ZnS | SiO₂ |
| ZnSe | ZnS | SiO₂ |
| ZnSeTe | ZnS | SiO₂ |
| CdSe | ZnS | SiO₂ |
| InP | ZnSe | ZnS |
| ZnSe | ZnSeS | ZnS |
| ZnSeTe | ZnSe | ZnS |
| CdSe | ZnSe | ZnS |
| CdSe | CdS | ZnS |
| InP | ZnSe | ZnSeS |
| ZnSe | ZnSe₁₋ₓSₓ | ZnSe_{1-y}S_{y} |
| ZnSeTe | ZnSe | ZnSeS |
| CdSe | ZnSe | ZnSeS |
| CdSe | CdS | ZnSeS |
| CdSe | CdS | ZnSe |

In the foregoing, 0 < x < y ≤ 1

The compositions of the first and second materials can be analyzed by observing the cross section of the light-emitting element 1 with a SEM, or observing, with a TEM, the cross section of the same that has undergone FIB processing, and by using EDX. The materials of the other constituents of the quantum dot QD, e.g., the materials of the first core C1, second core C2, and shell S1, can be analyzed similarly.

### Inorganic Matrix Member and Quantum Confinement Effect

FIG. 4 is a cross-sectional view of another example of the configuration of the emission layer illustrated in FIG. 1. As illustrated in FIG. 4, the emission layer Em may further include the inorganic matrix member Mx positioned between the first quantum dot QD1 and the second quantum dot QD2. The inorganic matrix member Mx may be in contact with the first layer K1 and the second layer K2.

The material of the inorganic matrix member Mx is different from the first material, which is contained in the first layer K1, and the second material, which is contained in the second layer K2. Each material may be selected in such a manner that the lattice constant of the first material falls between the lattice constant of the material of the shell S1 and the lattice constant of the material of the inorganic matrix member Mx. This reduces a mismatch in lattice constant between the first quantum dot QD1 and the inorganic matrix member Mx, thereby enabling reduction of lattice defects in the surface of the first quantum dot QD1. This lattice defect reduction can improve the emission efficiency of the first quantum dot QD1.

In the example illustrated in FIG. 4, the material of the first core C1 and the material of the second core C2 may be identical. In addition, the core diameters of the first core C1 and second core C2 may be equal; in addition, the material of the shell S1 may be identical to the second material, which is contained in the second layer K2; in addition, the thickness of the shell S1 may be equal to the thickness of the second layer K2.

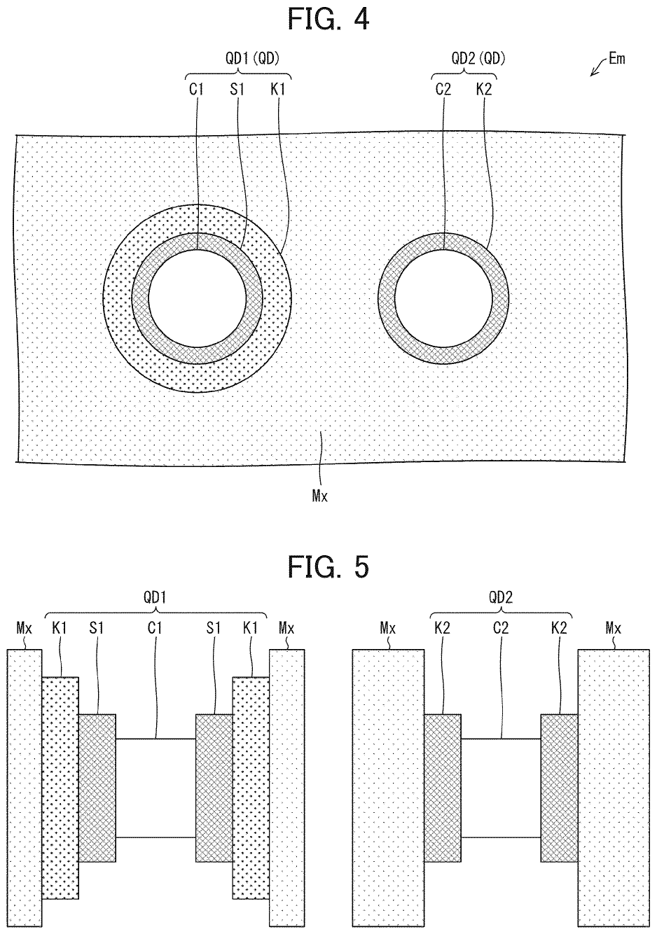

FIG. 5 illustrates an example of the energy band structure of the first and second quantum dots included in the emission layer illustrated in FIG. 4 with an inorganic matrix member included therein, and of the nearby inorganic matrix member. As shown in FIG. 5, the effective thickness of the inorganic matrix member Mx is smaller in the first quantum dot QD1 than in the second quantum dot QD2 by the thickness of the first layer K1. Thus, the quantum confinement effect on the excitons in the first core C1 is weaker than the quantum confinement effect on the excitons in the second core C2. Further, the electric-charge injection into the first quantum dot QD1 is easier than the electric-charge injection into the second quantum dot QD2. As a result, the light-emitting element 1 can enjoy a low turn-on voltage resulting from the first quantum dot QD1, and can thus improve the emission stability in a low-voltage region. The light-emitting element 1 can also enjoy a high upper limit of emission efficiency resulting from the second quantum dot QD2, and can thus improve the emission efficiency in a high-voltage region.

Table 2 shows some example combinations of inorganic matrix members in a case where an emission layer of a material that can be used in the light-emitting element according to one embodiment of the present disclosure includes inorganic matrix members. As shown in Table 2, the inorganic matrix member Mx may be formed from an insulating material, such as silicon oxide. Using silicon oxide, metal oxide, or other materials as the inorganic matrix member Mx can prevent impurities (e.g., water and oxygen), which can deteriorate the first quantum dot QD1 and the second quantum dot QD2, from reaching the surface of the quantum dot QD. Further, capping the quantum dots QD with the inorganic matrix member Mx so that the organic ligand member Rx does not detach itself from the first quantum dot QD1 and the second quantum dot QD2, can prevent the quantum dots QD from deterioration resulting from such detachment of the organic ligand member Rx.

TABLE 2

| First Core | Shell | | Inorganic Matrix |
|---|---|---|---|
| Second Core | Second Layer | First Layer | Member |
| InP | ZnSe | ZnS | SiO₂ |
| ZnSe | ZnSeS | ZnS | SiO₂ |
| ZnSeTe | ZnSe | ZnS | SiO₂ |
| CdSe | ZnSe | ZnS | SiO₂ |
| CdSe | CdS | ZnS | SiO₂ |
| InP | ZnSe | ZnS | ZnMgS |
| ZnSe | ZnSeS | ZnS | ZnMgS |
| ZnSeTe | ZnSe | ZnS | ZnMgS |
| CdSe | ZnSe | ZnS | ZnMgS |
| CdSe | CdS | ZnS | ZnMgS |
| InP | ZnSe | ZnSeS | ZnS |
| ZnSe | ZnSe₁₋ₓSₓ | ZnSe_{1-y}S_{y} | ZnS |
| ZnSeTe | ZnSe | ZnSeS | ZnS |
| CdSe | ZnSe | ZnSeS | ZnS |
| CdSe | CdS | ZnSe | ZnS |
| InP | ZnSe | ZnSe₁₋ₓSₓ | ZnSe_{1-y}S_{y} |
| ZnSe | ZnSe₁₋ₓSₓ | ZnSe_{1-y}S_{y} | ZnSe_{1-z}S_{z} |
| ZnSeTe | ZnSe | ZnSe₁₋ₓSₓ | ZnSe_{1-y}S_{y} |
| CdSe | ZnSe | ZnSe₁₋ₓSₓ | ZnSe_{1-y}S_{y} |

In the foregoing, 0 < x < y ≤ 1

### Production Method

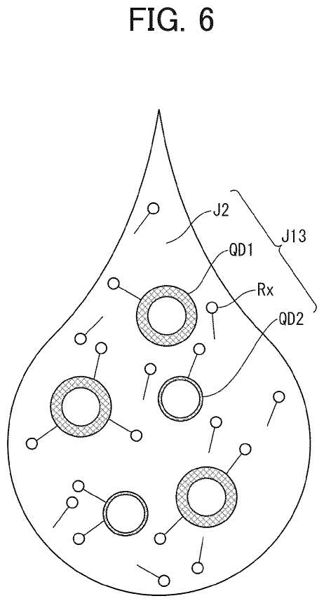

FIG. 6 is a schematic diagram illustrating an example of a quantum-dots-dispersed solution for the emission layer illustrated in FIG. 2. As illustrated in FIG. 6, a quantum-dots-dispersed solution J13 contains the first quantum dot QD1, the second quantum dot QD2, the organic ligand member Rx, and a solvent J2. The quantum-dots-dispersed solution J13 may contain other materials, such as a halogen. In one example of a method for producing the quantum-dots-dispersed solution, the first step is forming a plurality of second quantum dots QD2, followed by forming the first layer K1 onto only the core surfaces of some of the second quantum dots QD2 to form the first quantum dot QD1. The next is forming the quantum-dots-dispersed solution J13 by mixing the first quantum dot QD1, the second quantum dots QD2, the organic ligand member Rx, and the solvent J2.

Referring again to FIG. 1, the quantum-dots-dispersed solution J13 is applied onto the upper surface of the anode E1, for instance, onto the first functional layer F1. The next is heating the applied quantum-dots-dispersed solution J13 with the heat-resistance temperature of the organic ligand member Rx in mind, to form the emission layer Em.

### Second Embodiment

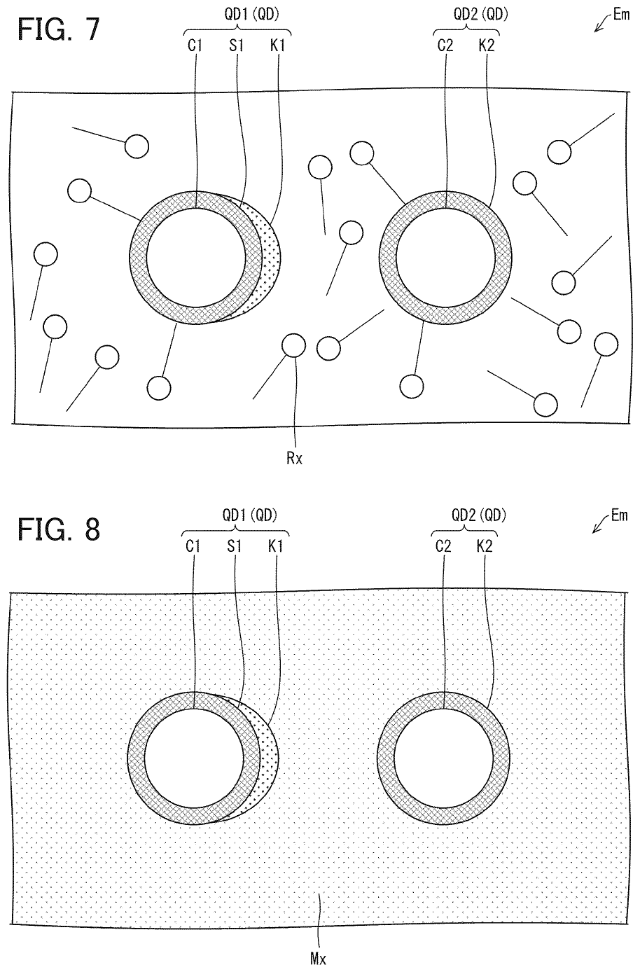

FIG. 7 is a cross-sectional view of an example of the configuration of the emission layer in the light-emitting element according to one embodiment of the present disclosure. FIG. 8 is a cross-sectional view of another example of the configuration of the emission layer in the light-emitting element according to the embodiment of the present disclosure. As illustrated in FIGS. 7 and 8, the first layer K1 may be a non-covering type being in contact with a part of the shell S1. The first layer K1 that covers the surface of the shell S1 without any gaps in cross-sectional view of a quantum dot (that is, K1 occupies the S1 surface 100%) is referred to as a covering type, whereas the first layer K1 that does not so (that is, K1 occupies the S1 surface 0 to 100% exclusive) is referred to as a non-covering type. An emission layer that includes quantum dots QD whose occupancy rates are 50% or greater different in cross-sectional observation in one direction is regarded as including quantum dots QD whose occupancy rates are significantly different even in view of the fact that the value of their occupancy rate can vary depending on a direction of observation, and such an emission layer exhibits the effect according to this embodiment.

When the emission layer Em includes the organic ligand member Rx as illustrated in FIG. 7, the excitons in the first core C1 need to pass through the shell S1 and need to stochastically pass through the first layer K1, in order to go out of the first quantum dot QD1. The probability that the excitons have to pass through the first layer K1 depends on the occupancy rate of the first layer K1 on the surface of the shell S1. Thus, the quantum confinement effect in the first quantum dot QD1 depends on the occupancy rate of the first layer K1 and is stronger than the quantum confinement effect in the second quantum dot QD2. Further, depending on the occupancy rate of the first layer K1, the electric-charge injection into the first quantum dot QD1 is more difficult than the electric-charge injection into the second quantum dot QD2.

As a result, even when the first layer K1 is a non-covering type, the light-emitting element 1 that has the emission layer Em that includes the organic ligand member Rx can enjoy a low turn-on voltage resulting from the second quantum dot QD2, and enjoy a high upper limit of emission efficiency resulting from the first quantum dot QD1, like the light-emitting element 1 according to the first embodiment. The organic ligand member Rx may include an organic ligand member being in contact with the shell S1, an organic ligand member being in contact with the first layer K1, and an organic ligand member being in contact with the second layer K2.

When the emission layer Em includes the inorganic matrix member Mx as illustrated in FIG. 8, when compared to the second quantum dot QD2, the first quantum dot QD1 is structured such that the effective thickness of the inorganic matrix member Mx is small in accordance with the occupancy rate and thickness of the first layer K1, like the first quantum dot QD1 according to the first embodiment. As a result, even when the first layer K1 is a non-covering type, the light-emitting element 1 that has the emission layer Em that includes the inorganic matrix member Mx can enjoy a low turn-on voltage resulting from the first quantum dot QD1, and enjoy a high upper limit of emission efficiency resulting from the second quantum dot QD2, like the light-emitting element 1 according to the first embodiment.

As such, the light-emitting element 1 can improve the emission stability in a low-voltage region, and the emission efficiency in a high-voltage region, whether the emission layer includes an organic ligand member or an inorganic matrix member.

### Third Embodiment

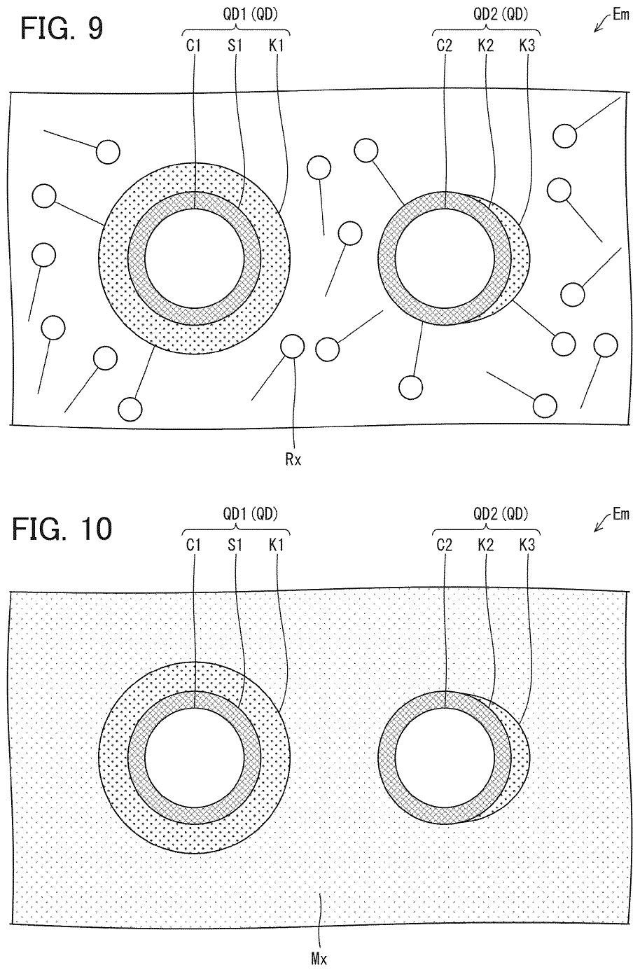

FIG. 9 is a cross-sectional view of an example of the configuration of the emission layer in the light-emitting element according to one embodiment of the present disclosure. FIG. 10 is a cross-sectional view of another example of the configuration of the emission layer in the light-emitting element according to the embodiment of the present disclosure. As illustrated in FIGS. 9 and 10, the second quantum dot QD2 may further include a third layer K3 being in contact with the second layer K2, and formed as a non-covering type containing the same material as the first material. The maximum thickness of the third layer K3 may be equal to or smaller than the maximum thickness of the first layer K1.

When the emission layer Em includes the organic ligand member Rx as illustrated in FIG. 9, the light-emitting element 1 can enjoy a low turn-on voltage resulting from the second quantum dot QD2, and enjoy a high upper limit of emission efficiency resulting from the first quantum dot QD1, like the light-emitting element 1 according to the first embodiment. The organic ligand member Rx may include an organic ligand member being in contact with the first layer K1, an organic ligand member being in contact with the second layer K2, and an organic ligand member being in contact with the third layer K3.

When the emission layer Em includes the inorganic matrix member Mx as illustrated in FIG. 10, the light-emitting element 1 can enjoy a low turn-on voltage resulting from the first quantum dot QD1, and enjoy a high upper limit of emission efficiency resulting from the second quantum dot QD2, like the light-emitting element 1 according to the first embodiment.

### Fourth Embodiment

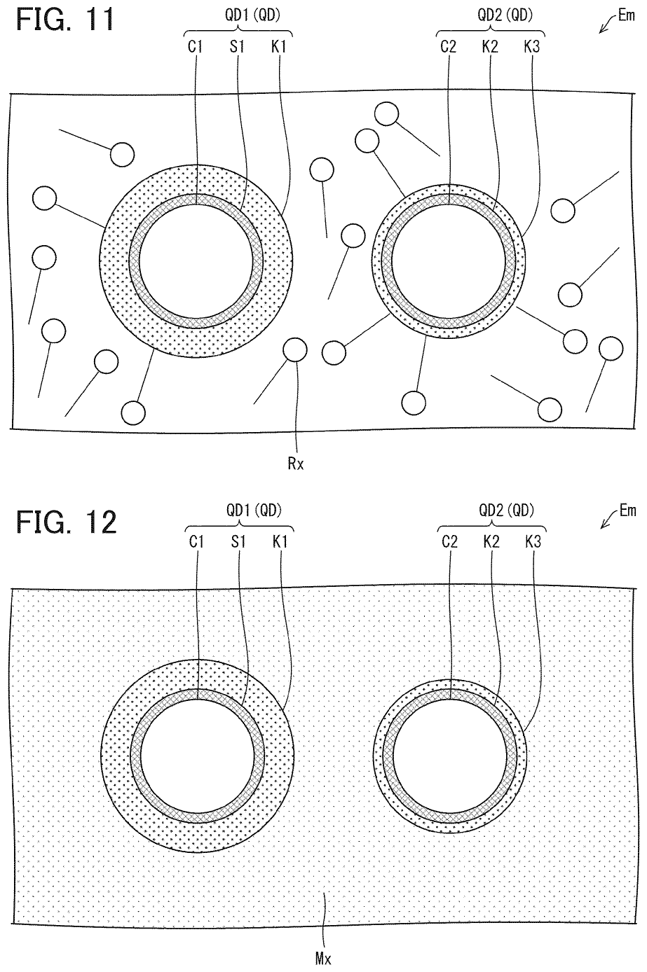

FIG. 11 is a cross-sectional view of an example of the configuration of the emission layer in the light-emitting element according to one embodiment of the present disclosure. FIG. 12 is a cross-sectional view of another example of the configuration of the emission layer in the light-emitting element according to the embodiment of the present disclosure. As illustrated in FIGS. 11 and 12, the first quantum dot QD1 may include the first layer K1 being a covering type; in addition, the second quantum dot QD2 may include the third layer K3 being in contact with the second layer K2, and formed as a covering type containing the same material as the first material; in addition, the average thickness of the third layer K3 may be smaller than the average thickness of the first layer K1.

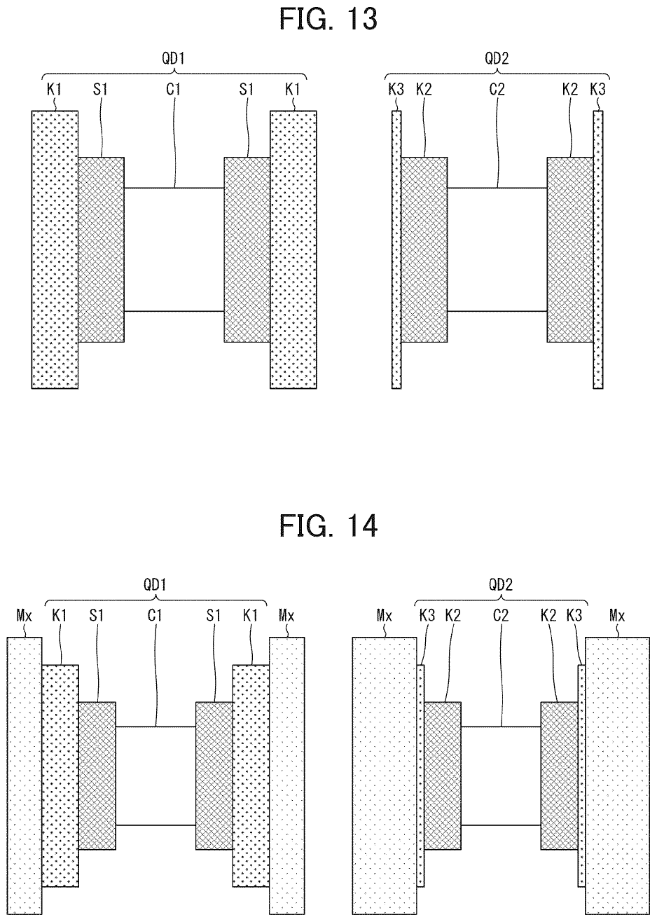

FIG. 13 illustrates an example of the energy band structure of the first and second quantum dots included in the emission layer illustrated in FIG. 11 with an organic ligand member included therein. As illustrated in FIG. 13, the excitons in the first core C1 need to pass through an energy barrier formed by the shell S1 and first layer K1, by tunnel effect in order to go out of the first quantum dot QD1. In addition, the excitons in the second core C2 need to pass through an energy barrier formed by the second layer K2, by tunnel effect in order to go out of the second quantum dot QD2.

The probability of passing through the first layer K1 and the probability of passing through the third layer K3 can be calculated by applying a tunnel transmittance T to an energy barrier. Equation (1) below indicates the tunnel transmittance T to an energy barrier, where d denotes thickness, and where AE denotes energy difference.

$$\begin{matrix}[ Numeral 1 ] & \\ T = exp ( - \frac{d}{{d}_{0}} ) & ( 1 )\end{matrix}$$

$$Here ,$$

$$\begin{matrix}[ Numeral 2 ] & \\ {d}_{0} = \frac{ℏ}{2 \sqrt{2 m Δ E}} & \end{matrix}$$

$$ℏ = h / ( 2 π )$$

It is noted that h denotes Planck constant, and that h=6.62×10⁻³⁴ J·s is established. It is also noted that m denotes electron mass, and that m=9.11×10⁻³¹ kg is established. It is also noted that elementary charge is 1.60×10⁻¹⁹ C.

As seen from Equation (1), the tunnel transmittance T decreases to 1/e every d₀ increase in the energy barrier's thickness. When the energy difference ΔE stands at 0.5 [eV], d₀=0.14 [nm] is established. When the probability of passing through the first layer K1 is equal to or greater than 100 times of the probability of passing through the third layer K3, it can be regarded that there is a significant difference in quantum confinement effect between the first quantum dot QD1 and the second quantum dot QD2. The thickness difference at which the difference in tunnel transmittance is 100 times is obtained through d₀×ln(100)=0.63 [nm]. Here, the function In is a natural logarithm. Thus, the first layer K1 is preferably thicker than the third layer K3 by 0.63 [nm] or greater.

Further, depending on the thickness difference between the first layer K1 and third layer K3, the electric-charge injection into the first quantum dot QD1 is more difficult than the electric-charge injection into the second quantum dot QD2. Thus, when the emission layer Em includes the organic ligand member Rx, the light-emitting element 1 can enjoy a low turn-on voltage resulting from the second quantum dot QD2, and enjoy a high upper limit of emission efficiency resulting from the first quantum dot QD1, like the light-emitting element 1 according to the first embodiment. The organic ligand member Rx may include an organic ligand member being in contact with the first layer K1, and an organic ligand member being in contact with the third layer K3.

FIG. 14 illustrates an example of the energy band structure of the first and second quantum dots included in the emission layer illustrated in FIG. 12 with an inorganic matrix member included therein, and of the nearby inorganic matrix member. When the emission layer Em includes the inorganic matrix member Mx, the light-emitting element 1 can enjoy a low turn-on voltage resulting from the first quantum dot QD1, and enjoy a high upper limit of emission efficiency resulting from the second quantum dot QD2, like the light-emitting element 1 according to the first embodiment.

### Fifth Embodiment

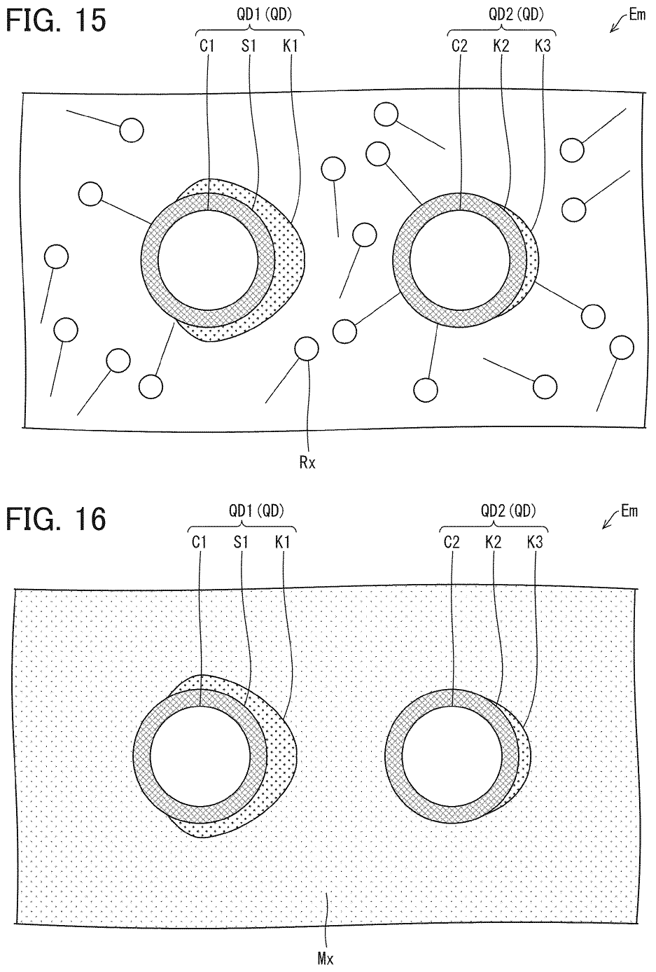

FIG. 15 is a cross-sectional view of an example of the configuration of the emission layer in the light-emitting element according to one embodiment of the present disclosure. FIG. 16 is a cross-sectional view of another example of the configuration of the emission layer in the light-emitting element according to the embodiment of the present disclosure. As illustrated in FIGS. 15 and 16, the second quantum dot QD2 may further include the third layer K3 being in contact with the second layer K2, and formed as a non-covering type containing the same material as the first material; in addition, the occupancy rate of the first layer K1 on the surface of the shell S1 may be larger than the occupancy rate of the third layer K3 on the surface of the second layer K2. The maximum thickness of the third layer K3 may be equal to or smaller than the maximum thickness of the first layer K1.

When the emission layer Em includes the organic ligand member Rx as illustrated in FIG. 15, the light-emitting element 1 can enjoy a low turn-on voltage resulting from the second quantum dot QD2, and enjoy a high upper limit of emission efficiency resulting from the first quantum dot QD1, like the light-emitting element 1 according to the first embodiment. The organic ligand member Rx may include an organic ligand member being in contact with the shell S1, an organic ligand member being in contact with the first layer K1, an organic ligand member being in contact with the second layer K2, and an organic ligand member being in contact with the third layer K3.

When the emission layer Em includes the inorganic matrix member Mx as illustrated in FIG. 16, the light-emitting element 1 can enjoy a low turn-on voltage resulting from the first quantum dot QD1, and enjoy a high upper limit of emission efficiency resulting from the second quantum dot QD2, like the light-emitting element 1 according to the first embodiment.

### Sixth Embodiment

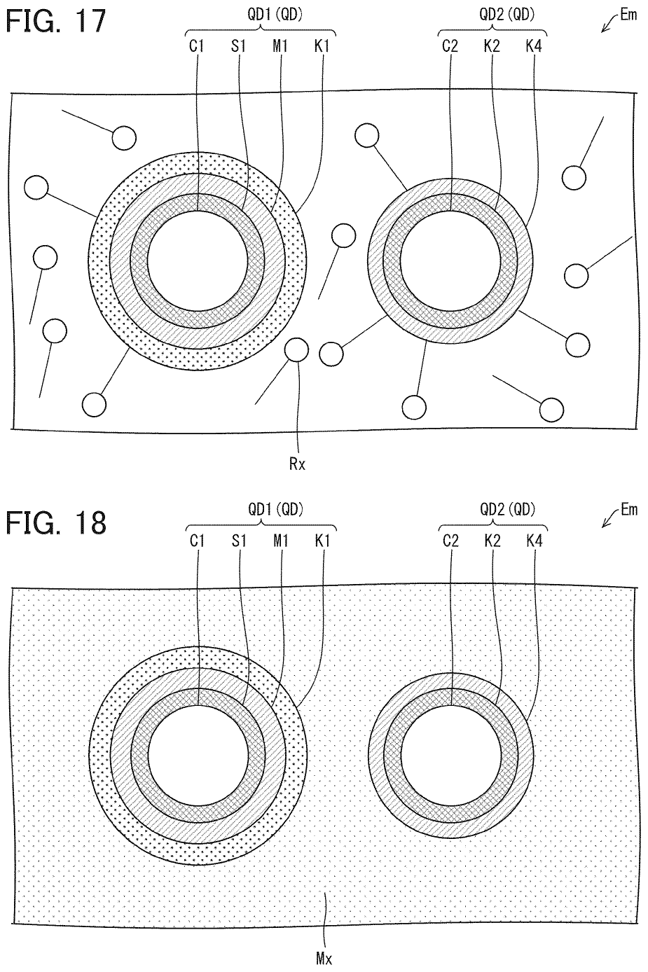

FIG. 17 is a cross-sectional view of an example of the configuration of the emission layer in the light-emitting element according to one embodiment of the present disclosure. FIG. 18 is a cross-sectional view of another example of the configuration of the emission layer in the light-emitting element according to the embodiment of the present disclosure. As illustrated in FIGS. 17 and 18, the first quantum dot QD1 may include a middle layer M1 positioned between the shell S1 and the first layer K1, and the second quantum dot QD2 may include a fourth layer K4 being in contact with the second layer K2, and formed as a covering type covering the whole of the second layer K2 and containing the same material as the middle layer M1. The thickness of the fourth layer K4 may be equal to the thickness of the middle layer M1.

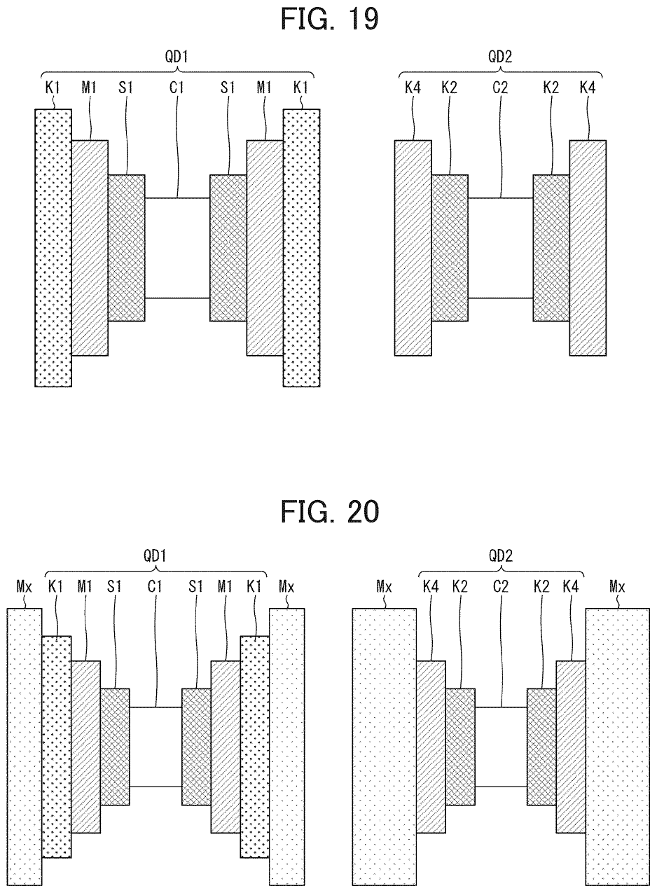

FIG. 19 illustrates an example of the energy band structure of the first and second quantum dots included in the emission layer illustrated in FIG. 17 with an organic ligand member included therein. As illustrated in FIG. 19, the excitons in the first core C1 need to pass through an energy barrier formed by the shell S1, middle layer M1, and first layer K1, by tunnel effect in order to go out of the first quantum dot QD1. In addition, the excitons in the second core C2 need to pass through an energy barrier formed by the second layer K2 and fourth layer K4, by tunnel effect in order to go out of the second quantum dot QD2. As a result, the quantum confinement effect on the excitons in the first core C1 is stronger than the quantum confinement effect on the excitons in the second core C2. Further, the electric-charge injection into the first quantum dot QD1 is more difficult than the electric-charge injection into the second quantum dot QD2. Thus, when the emission layer Em includes the organic ligand member Rx, the light-emitting element 1 can enjoy a low turn-on voltage resulting from the second quantum dot QD2, and enjoy a high upper limit of emission efficiency resulting from the first quantum dot QD1, like the light-emitting element 1 according to the first embodiment. The organic ligand member Rx may include an organic ligand member being in contact with the first layer K1, and an organic ligand member being in contact with the fourth layer K4.

FIG. 20 illustrates an example of the energy band structure of the first and second quantum dots included in the emission layer illustrated in FIG. 18 with an inorganic matrix member included therein, and of the nearby inorganic matrix member. When the emission layer Em includes the inorganic matrix member Mx, the light-emitting element 1 can enjoy a low turn-on voltage resulting from the first quantum dot QD1, and enjoy a high upper limit of emission efficiency resulting from the second quantum dot QD2, like the light-emitting element 1 according to the first embodiment.

### Seventh Embodiment

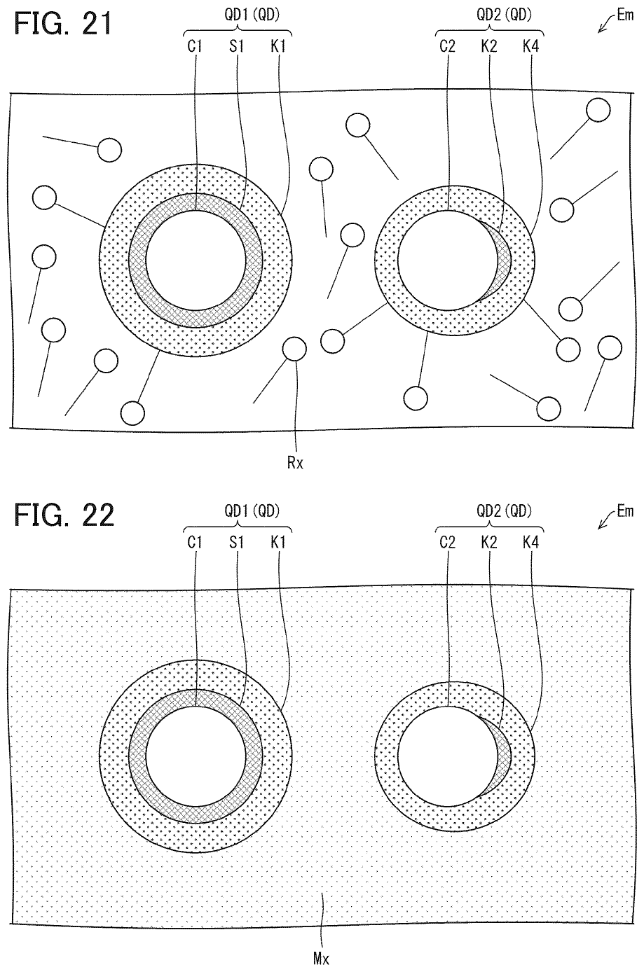

FIG. 21 is a cross-sectional view of an example of the configuration of the emission layer in the light-emitting element according to one embodiment of the present disclosure. FIG. 22 is a cross-sectional view of another example of the configuration of the emission layer in the light-emitting element according to the embodiment of the present disclosure. As illustrated in FIGS. 21 and 22, when the second quantum dot QD2 includes the fourth layer K4 formed as a covering type, the second layer K2 may be a non-covering type.

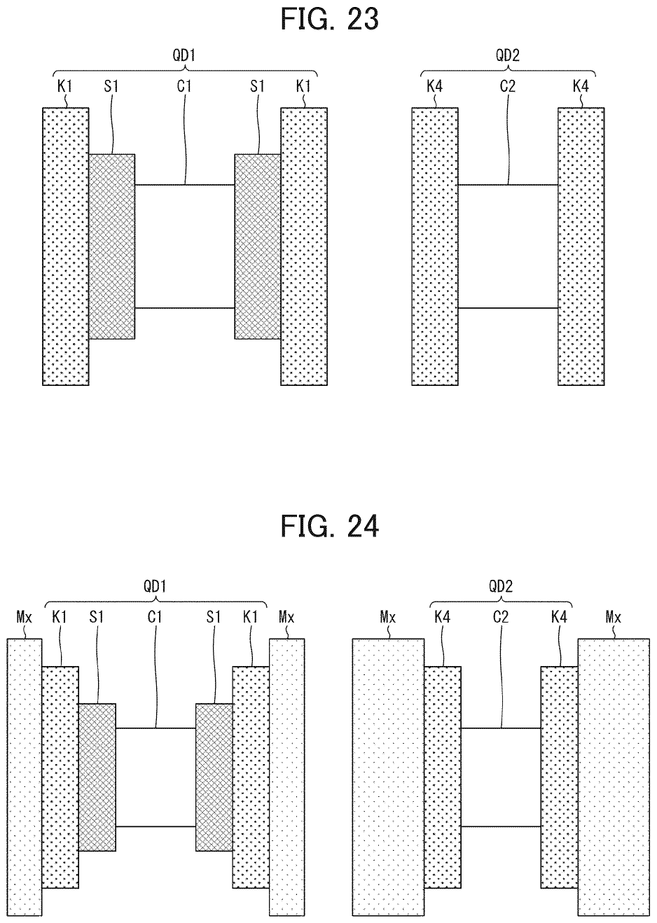

FIG. 23 illustrates an example of the energy band structure of the first and second quantum dots included in the emission layer illustrated in FIG. 21 with an organic ligand member included therein. When the emission layer Em includes the organic ligand member Rx, the light-emitting element 1 can enjoy a low turn-on voltage resulting from the second quantum dot QD2, and enjoy a high upper limit of emission efficiency resulting from the first quantum dot QD1, like the light-emitting element 1 according to the first embodiment. The organic ligand member Rx may include an organic ligand member being in contact with the first layer K1, and an organic ligand member being in contact with the fourth layer K4.

FIG. 24 illustrates an example of the energy band structure of the first and second quantum dots included in the emission layer illustrated in FIG. 22 with an inorganic matrix member included therein, and of the nearby inorganic matrix member. When the emission layer Em includes the inorganic matrix member Mx, the light-emitting element 1 can enjoy a low turn-on voltage resulting from the first quantum dot QD1, and enjoy a high upper limit of emission efficiency resulting from the second quantum dot QD2, like the light-emitting element 1 according to the first embodiment.

### Eighth Embodiment

### Configuration of Light-Emitting Element

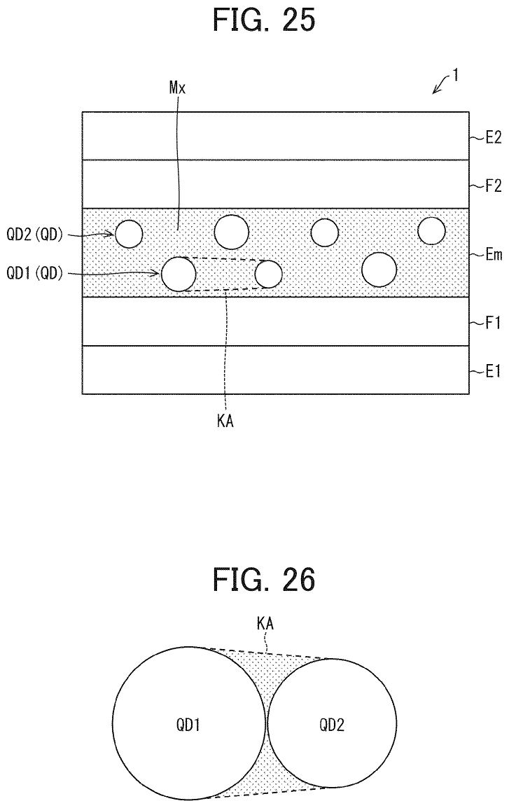

FIG. 25 is a cross-sectional view of an example of the configuration of a light-emitting element according to one embodiment of the present disclosure. As illustrated in FIG. 25, the light-emitting element 1 is provided with the anode E1 and the cathode E2 facing each other, and the emission layer Em positioned between the anode E1 and the cathode E2. The emission layer Em includes the first quantum dot QD1, the second quantum dot QD2, and the inorganic matrix member Mx. The second quantum dot QD2 emits light of the same color as the first quantum dot QD1, and has a smaller particle diameter than the first quantum dot by 1.26 [nm] or greater. The inorganic matrix member Mx is filled between the first quantum dot QD1 and the second quantum dot QD2.

It is noted that a quantum dot in the present disclosure means a dot having a maximum width of 100 nm or smaller. The quantum dot may have any shape that satisfies this maximum width; the shape is not limited to a spherical tridimensional shape (circular cross-section shape). For instance, the quantum dot may have a polygonal cross-section shape, a bar-shaped tridimensional shape, a branch-shaped tridimensional shape, a tridimensional shape having surface asperities, or a combination of them.

The quantum dot may be typically formed from a semiconductor. The semiconductor may have a constant band gap. The semiconductor may be a material capable of emitting light. Moreover, at least the following materials may be contained. The semiconductor may be able to emit red, green, and blue light individually. The semiconductor contains, for example, at least one selected from the group consisting of a Group II-VI compound, a Group III-V compound, a chalcogenide, and a perovskite compound. It is also noted that a Group II-VI compound is a compound containing a Group II element and a Group VI element, and that a Group III-V compound is a compound containing a Group III element and a Group V element. It is also noted that Group II elements can include group 2 elements and group 12 elements, that Group III elements can include group 3 elements and group 13 elements, that Group V elements can include group 5 elements and group 15 elements, and that Group VI elements can include group 6 elements and group 16 elements.

The Group II-VI compound contains at least one selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe for instance.

The Group III-V compound contains at least one selected from the group consisting of GaAs, GaP, InN, InAs, InP, and InSb for instance.

The chalcogenide is a compound containing a group VI A(16) element; for instance, it contains CdS or CdSe. The chalcogenide may contain a mixed crystal of these materials.

The perovskite compound has a composition represented by the general formula CsPbX3 for example. The constituent element X contains at least one selected from the group consisting of Cl, Br, and I for instance.

Here, the notation of element group numbers using Roman numerals is notation based on the former International Union of Pure and Applied Chemistry (IUPAC) system or the former Chemical Abstracts Service (CAS) system, and the notation of element group numbers using Arabic numerals is notation based on the current IUPAC system.

The light-emitting element 1 may be provided with a first functional layer F1 including one or more of a hole injection layer, a hole transport layer, and an electron blocking layer, between the anode E1 and the emission layer Em. The light-emitting element 1 may be provided with a second functional layer F2 including one or more of an electron injection layer, an electron transport layer, and a hole blocking layer, between the cathode E2 and the emission layer Em.

Examples of the hole transport layer include, but not limited to poly [(9,9-dioctylfluorenyl-2,7-diyl)-co-(4,4′-(N-4-sec-butylphenyl))diphenylamine)] (TFB for short), poly [N,N′-bis(4-butylphenyl)-N,N′-bis(phenyl)-benzidine] (p-TPD for short), and polyvinyl carbazole (PVK for short). These hole transport materials may be used alone, or in combination of two or more kinds as appropriate. Examples of the hole injection layer include, but not limited to, a composite (PEDOT: PSS for short) of poly(3,4-ethylenedioxythiophene) (PEDOT) and polystyrene sulfonic acid (PSS), nickel oxide (NiO), and copper thiocyanate (CuSCN). It is noted that these materials may be used alone, or in combination of two or more kinds as appropriate.

Examples of the electron transport layer include, but not limited to, zinc oxide (ZnO) nanoparticles, magnesium zinc oxide (MgZnO) nanoparticles, 2,2′,2″-(1,3,5-benzintriyl)-tris (1-phenyl-1-H-benzimidazole) (TPBi for short). These electron transport materials may be used alone, or in combination of two or more kinds as appropriate.

The light-emitting element 1, which includes the inorganic matrix member Mx filled between the first quantum dot QD1 and the second quantum dot QD2, can enhance the emission efficiency of the second quantum dot QD2 with a small particle diameter and can prevent deterioration in the second quantum dot QD2. The light-emitting element 1, which includes the first quantum dot QD1 with a large particle diameter, can improve emission variability in a low-voltage region. Hereinafter, the first quantum dot QD1 and the second quantum dot QD2 will be generically referred to as a quantum dot QD in some cases.

### Inorganic Matrix Member

The inorganic matrix member Mx means a member containing and retaining another substance, and can be also referred to as a base, a base material, or a filler. The inorganic matrix member Mx may be a solid at room temperature. The inorganic matrix member Mx may be a member containing and retaining a plurality of quantum dots QD. The inorganic matrix member Mx may be a constituent of the emission layer Em containing a plurality of quantum dots QD.

FIG. 26 is a schematic diagram illustrating an example of a region between the quantum dots illustrated in FIG. 25. The inorganic matrix member Mx may be filled in the emission layer Em. As illustrated in FIG. 26, the inorganic matrix member Mx may be filled in a region (space) KA between the first quantum dot QD1 and the second quantum dot QD2. As illustrated in FIGS. 25 and 26, the region KA is a region surrounded, in cross-sectional view, by two straight lines (common outer tangent lines) circumscribing the perimeters of the first quantum dot QD1 and second quantum dot QD2, and by the perimeters of the first quantum dot QD1 and second quantum dot QD2 facing each other. As illustrated in FIG. 26, the region KA can be present even if the first quantum dot QD1 is close to the second quantum dot QD2. The inorganic matrix member Mx may be filled in a region (space) in the emission layer Em, other than the region with the plurality of quantum dots QD.

The fact that the inorganic matrix member Mx is filled between the plurality of quantum dots QD means that the region KA between two quantum dots QD adjacent to each other like this, is filled with the inorganic matrix member Mx, and it is sufficient to know this fact. The inorganic matrix member Mx exerts a desired effect at least in the region KA between the two adjacent quantum dots QD; accordingly, there is not necessarily a need to know that the inorganic matrix member Mx is filled between all (more than two) quantum dots QD within a certain range.

The outer edge (the upper and lower surfaces) of the emission layer Em may be covered with the inorganic matrix member Mx. Further, the inorganic matrix member Mx may partly extend from the outer edge of the emission layer Em, and a group of quantum dots may be located away from the outer edge. The outer edge of the emission layer Em is not formed only from the inorganic matrix member Mx; the group of quantum dots may be partly exposed from the inorganic matrix member Mx. The inorganic matrix member Mx may be a portion of the emission layer Em excluding the group of quantum dots.

The inorganic matrix member Mx may incorporate the first quantum dot QD1 and the second quantum dot QD2. The inorganic matrix member Mx may incorporate a plurality of quantum dots QD1 including the first quantum dot QD1 and second quantum dot QD2. The inorganic matrix member Mx may be formed so as to be filled partly or completely in the space KA, which is formed between the first quantum dot QD1 and the second quantum dot QD2. The emission layer Em may have a gap inside. The emission layer Em may have a plurality of quantum dots QD including the first quantum dot QD1 and second quantum dot QD2, and the inorganic matrix member Mx may be filled partly or completely in a region excluding the plurality of quantum dots QD. The first quantum dot QD1 and the second quantum dot QD2 may be embedded in the inorganic matrix member Mx at an interval.

The inorganic matrix member Mx may include a continuous film having an area of 1000 nm² or greater along a plane orthogonal to the thickness direction of the emission layer Em. The continuous film means a film that cannot be divided, in one plane, by a material other than materials constituting the continuous film. The continuous film may be an integral film in which the materials constituting the inorganic matrix member Mx are coupled together without interruption through chemical bonding.

The inorganic matrix member Mx may be the same material as the shells of the group of quantum dots including the first quantum dot QD1 and second quantum dot QD2. In this case, the average distance between cores adjacent to each other (core-to-core distance) may measure 3 nm or greater, and may measure 5 nm or greater. Alternatively, the average distance between the adjacent cores may be 0.5 times or greater of an average core diameter. The core-to-core distance is the average of the distances between 20 cores adjacent to each other in a space including the 20 cores. The core-to-core distance may be kept wider than a distance that is produced by shells being in contact with each other. The average core diameter is the average of the core diameters of 20 cores in cross-sectional view in a space including the 20 cores. Each core diameter can be defined as the diameter of a circle having the same area as the core's area in cross-sectional view.

The concentration of the inorganic matrix member Mx in the emission layer Em is, for example, the area ratio of the inorganic matrix member Mx in the cross-section of the emission layer Em. The concentration may stand at 10 to 90% inclusive in cross-sectional view, and may stand at 30 to 70% inclusive in cross-sectional view. The concentration may be measured from, for instance, an area proportion in cross-sectional image processing. When the group of quantum dots has a core-shell structure, the shell's concentration may stand at 1 to 50% inclusive. When the shell and the inorganic matrix member Mx are the same material (same composition), and the shell and the inorganic matrix member Mx cannot be distinguished from each other, a combined region of the shell and inorganic matrix member Mx may have a concentration that falls within a numerical range obtained by adding the numerical range of the concentration of the shell to the numerical range of the concentration of the inorganic matrix member Mx. The ratios of the core and shell of the group of quantum dots, and of the inorganic matrix member Mx may be adjusted so that their total ratio stands at appropriately 100% or less. When the shell and the inorganic matrix member Mx cannot be distinguished from each other as described above, the shell may be a part of the inorganic matrix member Mx.

Unless otherwise specified or contradictory, the structure of the inorganic matrix member Mx may be observed in a width of about 100 nm in the cross-sectional view of the emission layer Em as long as the structure is found to have the above-described configuration, and the above-described configuration need not be observed in the entire emission layer Em. The inorganic matrix member Mx may contain a substance different from its main material (e.g., an inorganic substance, such as an inorganic semiconductor) as an additive for instance. The observation result of the portion of the emission layer Em may be applied to the entire emission layer Em.

### Configuration of Emission Layer

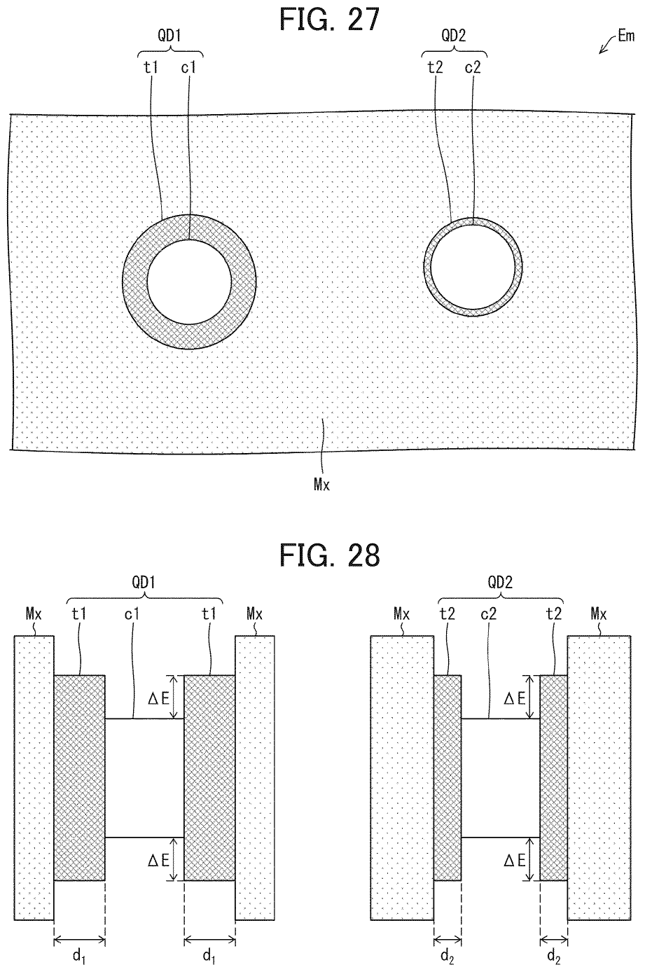

FIG. 27 is a cross-sectional view of an example of the configuration of the emission layer illustrated in FIG. 25. As illustrated in FIG. 27, the first quantum dot QD1 and the second quantum dot QD2 may respectively include a core c1 and a core c2 that contain an identical core material. The particle diameters of the cores c1 and c2 may measure 3 to 10 [nm]. The particle diameters of the cores c1 and c2 may be equal. The inorganic matrix member Mx may contain a matrix material having a larger band gap than the core material.

In the present disclosure, the expression “equal particle diameters” encompasses not only a case where the particle diameters are exactly the same, but also a case where the difference in particle diameter is sufficiently small. For example, when the difference in particle diameter between the cores c1 and c2 ranges from 0.2 to 0.3 [nm], the particle diameters of the core c1 and c2 are equal irrespective of the particle diameter of the core c1.

A first middle layer t1 containing a material different from the core material and matrix material may be positioned between the core c1 of the first quantum dot QD1 and the inorganic matrix member Mx. A second middle layer t2 containing a material different from the core material and matrix material may be positioned between the core c2 of the second quantum dot QD2 and the inorganic matrix member Mx. The first middle layer t1 may be thicker than the second middle layer t2 by 0.63 [nm] or greater.

In the present disclosure, the thickness of the first middle layer t1 may be calculated by dividing, by two, the difference between the particle diameter of the first quantum dot QD1 and the particle diameter of the core c1 of the first quantum dot QD1. Likewise, the thickness of the second middle layer t2 may be calculated by dividing, by two, the difference between the particle diameter of the second quantum dot QD2 and the particle diameter of the core c2 of the second quantum dot QD2.

The band gap of the first middle layer t1 may be larger than the band gap of the core c1 of the first quantum dot QD1, and smaller than the band gap of the inorganic matrix member Mx. The band gap of the second middle layer t2 may be larger than the band gap of the core c2 of the second quantum dot QD2, and smaller than the band gap of the inorganic matrix member Mx. The second middle layer t2 may be made of the same material as the first middle layer t1.

The first middle layer t1 may be the shell of the first quantum dot QD1. The second middle layer t2 may be the shell of the second quantum dot QD2. In other words, each of the first quantum dot QD1 and second quantum dot QD2 may be a core-shell type having a core, and a shell formed in at least a part of the core's surface. The shell's thickness may be about 1 to 5 times the lattice constant of a material constituting the shell, in order to reduce defects in the shell and the quantum dot having the shell. For example, when the material of the first middle layer t1 has a lattice constant of 0.55 to 0.65 [nm], the first middle layer t1 may have a thickness of about 0.5 to 2.5 [nm]. For example, when the material of the second middle layer t2 has a lattice constant of 0.55 to 0.65 [nm], the second middle layer t2 may have a thickness of about 0.5 to 2.5 [nm]. The surface of the second quantum dot QD2 is protected by the inorganic matrix member Mx. Hence, the second quantum dot QD2 and the core c2 are less likely to deteriorate even when the second middle layer t2 is thin.

The first middle layer t1 and the second middle layer t2 may be made of the same material. The material of the first middle layer t1 and the matrix material may contain one or more common elements. These common elements may include at least one of zinc (Zn), sulfur(S), and selenium (Se). The matrix material may include a metal chalcogenide; for example, the matrix material may include a metal sulfide. The core material of the cores c1 and c2, the materials of the first middle layer t1 and second middle layer t2, and the matrix material of the inorganic matrix member Mx may be combined based on any combination shown in Table 3 below. It is to be understood that the composition ratios of the respective materials may differ from stoichiometric composition ratios (stoichiometry) except for those specified in the table (ZnMg₁₋ₓOₓ, and ZnMg_{1-y}S_{y} in Table 3), and that each material may include a doped material or an impurity.

TABLE 3

| | | Inorganic Matrix |
|---|---|---|
| Core | Middle Layer | Member |
| InP | ZnS | ZnMgS |
| ZnSe | ZnS | ZnMgS |
| ZnSeTe | ZnS | ZnMgS |
| CdSe | ZnS | ZnMgS |
| InP | ZnSe | ZnS |
| ZnSe | ZnSeS | ZnS |
| ZnSeTe | ZnSe | ZnS |
| AgGaSeS | ZnSe | ZnS |
| CdSe | ZnSe | ZnS |
| CdSe | CdS | ZnS |
| AgGaSeS | GaSe | GaS |
| InP | ZnSe | ZnSeS |
| ZnSe | ZnSe₁₋ₓSₓ | ZnSe_{1-y}S_{y} |
| ZnSeTe | ZnSe | ZnSeS |
| AgGaSeS | ZnSe | ZnSeS |
| CdSe | ZnSe | ZnSeS |
| AgGaSeS | GaSe | GaSeS |

In the foregoing, 0 < x < y ≤ 1

The emission layer Em may include a plurality of quantum dots of the same kind as the first quantum dot QD1, and a plurality of quantum dots of the same kind as the second quantum dot QD2 at a dot ratio of k:(1−k). The first quantum dot QD1 is denoted by k in the dot ratio, and the second quantum dot QD2 is denoted by (1−k) in the dot ratio. The “same kind” means the same material and same configuration. To be specific, the quantum dots of the same kind as the first quantum dot QD1 have their cores whose materials are the same as that of the core c1 of the first quantum dot QD1, and whose particle diameters are equal to that of the core c1 of the first quantum dot QD1, and these same kind of quantum dots have their middle layers whose materials are the same as that of the first middle layer t1, and whose thicknesses are equal to that of the first middle layer t1. The quantum dots of the same kind as the second quantum dot QD2 have their cores whose materials are the same as that of the core c2 of the second quantum dot QD2, and whose particle diameters are equal to that of the core c2 of the second quantum dot QD2, and these same kind of quantum dots have their second middle layers t2 whose materials are the same as that of the second middle layer t2, and whose thicknesses are equal to that of the second middle layer t2. It is noted that 0.1<k<0.5 may be satisfied, and that 0.3<k<0.5 may be satisfied.

In the present disclosure, the expression “equal thicknesses” encompasses not only a case where the thicknesses are exactly the same, but also a case where the difference in thickness is sufficiently small. For example, when the first middle layer t1 has a thickness of 1.1 to 4.0 [nm], a 0.3 [nm] or less difference may be allowed. For example, when the second middle layer t2 has a thickness of 0.5 to 2.5 [nm], a 0.3 [nm] or less difference may be allowed.

The compositions of the core and middle layer of a quantum dot QD can be analyzed by observing the cross section of the light-emitting element 1 with a scanning electron microscope (SEM), or observing, with a transmission electron microscope (TEM), the cross section undergone focused ion beam (FIB) processing, and using an energy dispersive X-ray spectroscopy (EDX) apparatus.

### Quantum Confinement Effect

FIG. 28 illustrates an example of the energy band structure of the first and second quantum dots illustrated in FIG. 27, and of the nearby inorganic matrix member. The first middle layer t1 is thicker than the second middle layer t2, as illustrated in FIG. 27. Hence, the effective thickness of the inorganic matrix member Mx is smaller in the first quantum dot QD1 than in the second quantum dot QD2. An inorganic matrix member having a larger band gap than a core and a middle layer can effectively confine excitons in a quantum dot (that is, the inorganic matrix member has a large quantum confinement effect), but is less likely to feed current and is thus less likely to inject current into the quantum dot. That is, the first quantum dot QD1 is more likely to undergo current injection and has a smaller quantum confinement effect than the second quantum dot QD2. That is, the first quantum dot QD1 has a smaller turn-on voltage, and a smaller upper limit of emission efficiency.

In the present disclosure, the expression “near a quantum dot” encompasses a range that directly affects charge injection into the quantum dot, or the quantum confinement effect of the quantum dot. To be specific, the range includes the inside of a sphere in which the core's center of the quantum dot is its center, and in which its radius is equal to the expected value of the one-time traveling distance of a carrier conducting within the emission layer Em by hopping. Further, the “effective thickness of the inorganic matrix member Mx” is a value obtained by subtracting the radius of a sphere that is the first quantum dot QD1 or second quantum dot QD, from the expected value of the one-time traveling distance of the carrier conducting by hopping.

In the example illustrated in FIG. 28, an energy difference AE [eV] between the highest occupied molecular orbital (HOMO) of the core c1 of the first quantum dot QD1 and the HOMO of the first middle layer t1 is equal to an energy difference AE [eV] between the lowest unoccupied molecular orbital (LUMO) of the core c1 of the first quantum dot QD1 and the LUMO of the first middle layer t1. Also, in the second quantum dot QD2, the energy difference AE between the HOMOs is equal to the energy difference ΔE between the LUMOs. Further, the energy difference AE in the first quantum dot QD1 is equal to the energy difference AE in the second quantum dot QD2.

Let the thickness of the first middle layer t1 be denoted as di [nm], let the tunnel transmittance through the first middle layer t1 be denoted as T1, let the thickness of the second middle layer t2 be denoted as d₂ [nm], and let the tunnel transmittance through the second middle layer t2 be denoted as T2. Accordingly, Equations (1) and (2) below are established.

$${T}_{1} = exp [ - {d}_{1} / {d}_{0} ] \qquad ( 1 )$$

$${T}_{2} = exp [ - {d}_{2} / {d}_{0} ] \qquad ( 2 )$$

$$\begin{matrix}[ Numeral 3 ] & \\ {d}_{0} = \frac{ℏ}{2 \sqrt{2 m Δ E}} & \end{matrix}$$

$$\begin{matrix}[ Numeral 4 ] & \\ ℏ = h / ( 2 π ) & \end{matrix}$$

It is noted that h denotes Planck constant, and that h=6.62×10⁻³⁴ [J·s] is established.

It is also noted that m denotes electron mass, and that m=9.11×10⁻³¹ [kg] is established.

It is also noted that e denotes elementary charge, and that e=1.60×10⁻¹⁹ [C] is established.

Further, Equation (3) is established based on Equations (1) and (2), where Δd=d₁−d₂.

$${T}_{2} / {T}_{1} = exp [ Δ d / {d}_{0} ] \qquad ( 3 )$$

When the ratio of tunnel transmittance (T₂/T₁) between the first quantum dot QD1 and the second quantum dot QD2 is 100 times or greater, there is a significant difference in quantum confinement effect between the first quantum dot QD1 and the second quantum dot QD2. The difference Ad in thickness between the first middle layer t1 and the second middle layer t2 at which the tunnel transmittance ratio stands at 100 times is given by Equation (4) below.

$$Δ d = {d}_{0} \times ln [ 100 ] \qquad ( 4 )$$

Here, in ΔE=0.5 [eV], d₀=0.14 [nm] is established. Substituting d₀=0.14 [nm] into Equation (4) provides Δd=0.63 [nm]. It is thus preferable that the difference Δd in thickness between the first middle layer t1 of the first quantum dot QD1 and the second middle layer t2 of the second quantum dot QD2 be equal to or greater than 0.63 [nm]. Provided that the first middle layer t1 and the second middle layer t2 are formed on the entire surfaces of the respective cores 1 and 2 with a uniform thickness, a comparison can be made between the particle diameter of the first quantum dot QD1 and the particle diameter of the second quantum dot QD2; the difference in particle diameter between the first quantum dot QD1 and the second quantum dot QD2 is twice as large as the thickness difference Δd; the particle difference is preferably equal to or greater than 1.26 [nm] (=2×Δd).

### Quantum Dot

The emission layer Em may include a quantum dot of the same kind as the first quantum dot QD1, and a quantum dot of the same kind as the second quantum dot QD2. Hereinafter, the first quantum dot QD1 and the quantum dot of the same kind as the first quantum dot QD1 may be all-inclusively referred to as a “first quantum dot QD1”. In addition, the second quantum dot QD2 and the quantum dot of the same kind as the second quantum dot QD2 may be all-inclusively referred to as a “second quantum dot QD2”.

A quantum dot QD may or may not be a sphere, and the particle diameter of the quantum dot QD is the diameter of a circle having the same area as the cross-sectional area of the quantum dot QD. The cross-sectional area of the quantum dot QD may be the area of the quantum dot QD obtained through imaging with a transmission electron microscope (TEM) or other equipment.

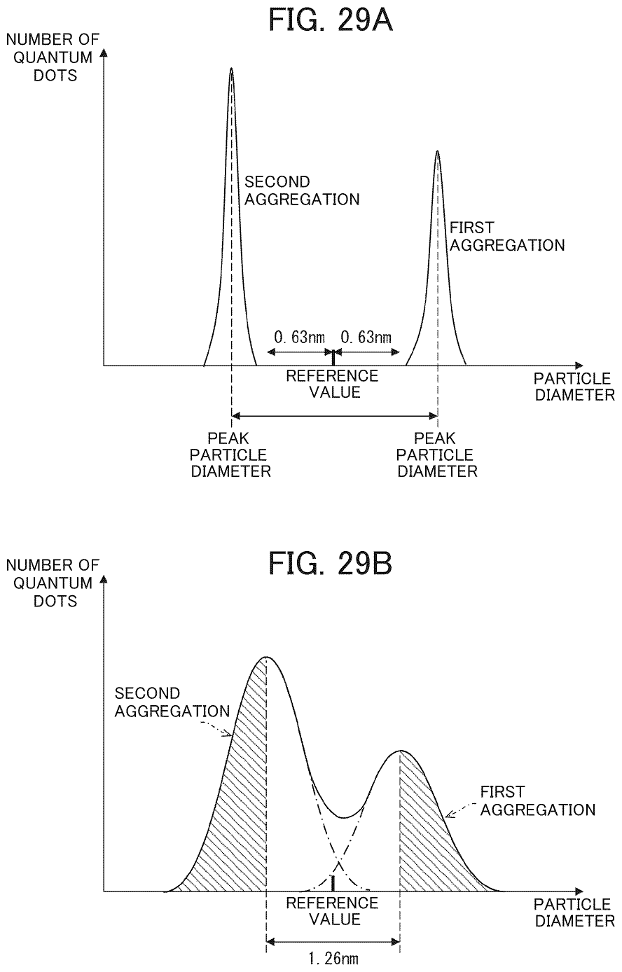

FIGS. 29A and 29B are graphs showing the particle diameter distribution of quantum dots in the emission layer. As shown in FIGS. 29A and 29B, in the light-emitting element 1, two peaks (maximum values) may appear in the particle diameter distribution (particle diameter-number) of a group of quantum dots (for example, a group of 50 quantum dots) observed in the emission layer Em with a TEM or other equipment, and the interval between the two peaks (the difference between a larger peak particle diameter and a smaller peak particle diameter) may measure 1.26 [nm] or greater. Three or more peaks may appear in the particle diameter distribution; in this case, when attention is directed to the largest particle diameter peak and the smallest particle diameter peak, the interval between the two peaks of interest may measure 1.26 [nm] or greater.

The first quantum dot QD1 may be included in a first aggregation that has a particle diameter larger than a reference particle diameter, which is the intermediate value of the two peaks, by 0.63 [nm] or greater; in addition, the second quantum dot QD2 may be included in a second aggregation that has a particle diameter smaller than the reference particle diameter by 0.63 [nm] or greater. That is, the first aggregation consists of a plurality of quantum dots of the same kind as the first quantum dot QD1, and the second aggregation consists of a plurality of quantum dots of the same kind as the second quantum dot QD2. The reference particle diameter may measure 1.0 to 20.0 [nm].

It should be noted that, as shown in FIG. 29B, a quantum dot in which the difference between its particle diameter and the reference particle diameter is less than 0.63 [nm] belongs to neither the first aggregation nor the second aggregation. That is, the mountain having a larger peak and the first aggregation do not coincide in some cases. Likewise, the mountain having a smaller peak and the first aggregation do not coincide in some cases. The proportion of quantum dots that do not belong to either the first aggregation or the second aggregation may stand at 0 to 20% of all quantum dots.

In the group of quantum dots, the plurality of quantum dots of the same kind as the first quantum dot QD1 (these quantum dots belong to the first aggregation) may be less than the plurality of quantum dots of the same kind as the second quantum dot QD2 (these quantum dots belong to the second aggregation). Since the first quantum dot QD1 is more likely to undergo current injection than the second quantum dot QD2, when there are as many first quantum dots QD1 as the second quantum dots QD2, a larger current flows through the first quantum dots QD1 than through the second quantum dots QD2; consequently, the emission efficiency, L, of the light-emitting element 1 becomes prominently lower than the simple average, (L1+L2)/2, of the emission efficiency, L1, of the first quantum dot QD1 and the emission efficiency, L2, of the second quantum dot QD2. For this reason, it is preferable that the number in the first aggregation be smaller than the number in the second aggregation in order to enhance the emission efficiency L of the light-emitting element 1 particularly at a large current.

The light-emitting element 1, which includes the inorganic matrix member Mx filled between the first quantum dot QD1 and the second quantum dot QD2, can enhance the emission efficiency of the second quantum dot QD2 with a small particle diameter and can prevent deterioration in the second quantum dot QD2. Moreover, the light-emitting element 1, which includes the first quantum dot QD1 with a large particle diameter, can improve emission variability in a low-voltage region.

### Manufacturing Method

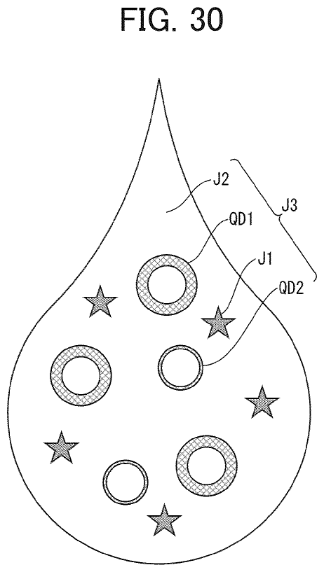

FIG. 30 is a schematic diagram illustrating an example of a quantum-dots-dispersed solution for the emission layer illustrated in FIG. 25. As illustrated in FIG. 30, a quantum-dots-dispersed solution J3 contains the first quantum dot QD1, a plurality of second quantum dots QD2, a precursor J1 of the inorganic matrix member Mx, and the solvent J2. The quantum-dots-dispersed solution J3 may contain other materials, such as an organic ligand member or a halogen. In one example of a method for producing the quantum-dots-dispersed solution, the first step is forming cores for multiple quantum dots QD. The core may be synthesized through any method, and the core may be synthesized using a conventional technique. The next is dividing the cores into the core c1 for the first quantum dot QD1, and the core c2 for the second quantum dot QD2 at a core ratio of k:(1−k).

The next is forming the first middle layer t1 onto at least a part of the surface of the core c1, which is for the first quantum dot QD1, to form the first quantum dot QD1. Here, the first quantum dot QD1 may be formed by adding a precursor of a material that constitutes the first middle layer t1 into a solution containing the core c1, to cause the precursor to react. For example, when the first middle layer t1 contains zinc sulfide (ZnS), a zinc source, such as zinc carboxylate, and a sulfur source, such as phosphine sulfide, are added into the solution, and the solution undergoes heating and cooling as appropriate. Likewise, the second quantum dot QD2 is simultaneously formed by forming the second middle layer t2 onto at least a part of the surface of the core c2, which is for the second quantum dot QD2.

In the individual formation of the first middle layer t1 and second middle layer t2, the thicknesses of the first middle layer t1 and second middle layer t2 can be controlled by regulating, but not limited to, the amount of precursor addition, the number of times of precursor addition, and the time for precursor reaction.

The next is forming the quantum-dots-dispersed solution J3 by mixing the first quantum dot QD1, the second quantum dots QD2, the precursor J1 of the inorganic matrix member Mx, and the solvent J2. The precursor J1 is a material that can be transformed into the inorganic matrix member Mx by heating. When the inorganic matrix member Mx contains zinc magnesium sulfide (ZnMgS), the precursor J1 may contain a zinc source, such as zinc carboxylate, a magnesium source, such as magnesium carboxylate, and a sulfur source, such as thiourea. When the inorganic matrix member Mx contains zinc sulfide selenide (ZnSSe), the precursor J1 may contain a zinc source, a sulfur source, and a selenium source, such as selenourea. The solvent J2 may contain an organic solvent, such as N,N-dimethylformamide (DMF).

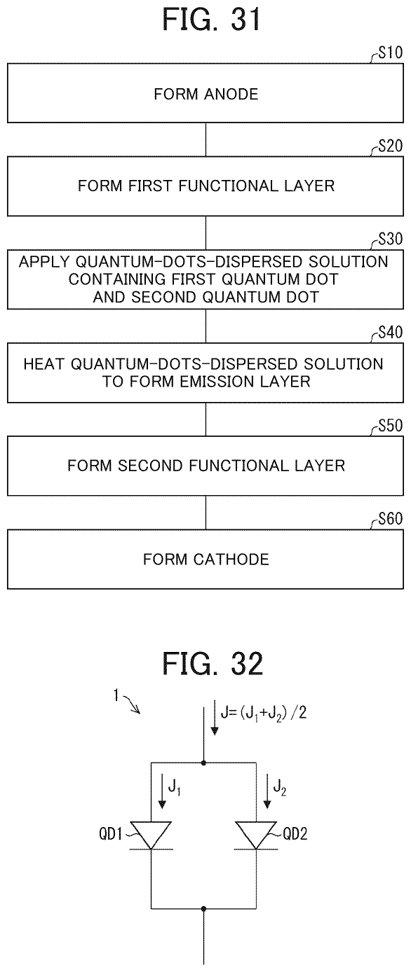

FIG. 31 is a flowchart showing an example of a method for manufacturing the light-emitting element illustrated in FIG. 25. As shown in FIG. 31, the method includes the following: forming the anode E1 above a substrate (Step S10); forming the first functional layer F1 onto the anode E1 (Step S20); and applying the quantum-dots-dispersed solution J3 containing the first quantum dot QD1 and second quantum dots QD2 onto the first functional layer F1 (Step S30). The next is heating the applied quantum-dots-dispersed solution J3 to transform the precursor into the inorganic matrix member Mx, to form the emission layer Em (Step S40). The heating may be performed for about 30 minutes at 250 degrees Celsius when a material constituting the inorganic matrix member Mx is zinc sulfide (ZnS). The next is forming the second functional layer F2 onto the emission layer Em (Step S50), followed by forming the cathode E2 onto the second functional layer F2 (Step S60).

In this manufacturing method in the present disclosure, the emission layer Em can be formed through one-time application. On the other hand, in the manufacturing method described in Cited Literature 1, the emission layer is formed through two-time application. Accordingly, the manufacturing method in the present disclosure advantageously includes less process steps than the manufacturing method described in Cited Literature 1.

In the manufacturing method in the present disclosure, a plurality of first quantum dots QD1 and a plurality of second quantum dots QD2 are contained together in the quantum-dots-dispersed solution J3 and are randomly distributed in the coating film of the quantum-dots-dispersed solution J3. The average distance from the upper surface of the anode E1 to the plurality of first quantum dots QD1 is substantially the same as the average distance from the upper surface of the anode E1 to the plurality of second quantum dots QD2. Thus, the angle dependency of the plurality of first quantum dots QD1 and the angle dependency of the plurality of second quantum dots QD2 are substantially the same in the cavity between the anode E1 and cathode E2. In the configuration disclosed in Patent Literature 1 on the other hand, the average distance from a reflective electrode is different between a first quantum dot and a second quantum dot, and their angle dependencies resulting from a cavity effect are different. As such, when compared to that in the configuration described in Cited Literature 1, the emission angle dependency of the light-emitting element 1 in the configuration in the present disclosure is advantageously constant irrespective of the driving current or emission luminance of the light-emitting element 1.

### Example 1

An example of the present disclosure will be described below. FIG. 32 is a schematic circuit diagram of a light-emitting element according to Example 1. FIG. 32 illustrates the light-emitting element 1 in the form of a circuit in which a light-emitting element consisting only of the first quantum dot QD1 and a light-emitting element consisting only of the second quantum dot QD2 are connected in parallel. Let the density of current flowing through the light-emitting element consisting only of the first quantum dot QD1 be denoted as J1, and let the density of current flowing through the light-emitting element consisting only of the second quantum dot QD2 be denoted as J2. The first quantum dot QD1 and second quantum dot QD2 according to Example 1 have the same configuration with the exception that the first middle layer t1 is thicker than the second middle layer t2 (Δd >0). The energy difference AE stands at 0.5 [eV].

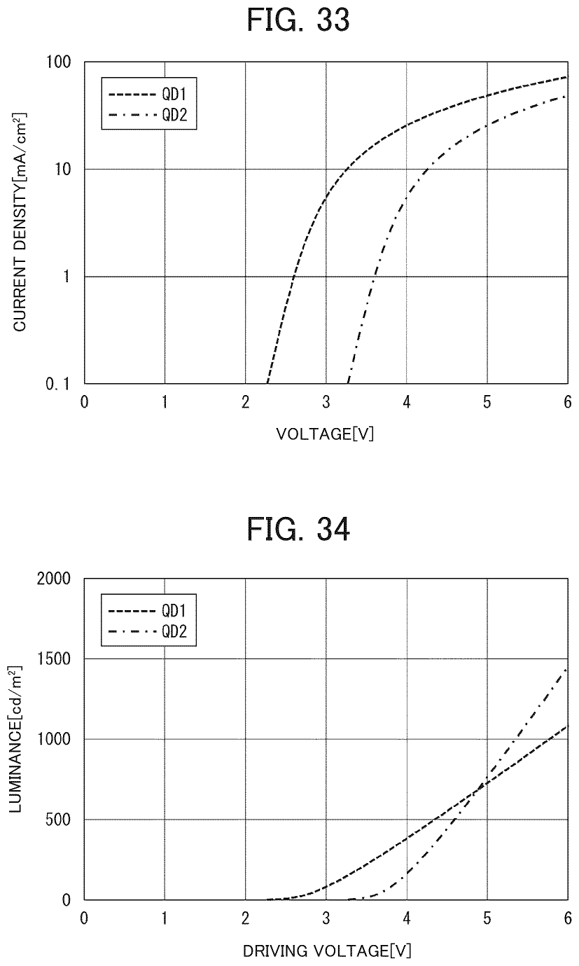

FIG. 33 is a graph showing the relationship between current density [mA/cm²], and the driving voltage [V] of the light-emitting element consisting only of the first quantum dot illustrated in FIG. 32 as well as the driving voltage [V] of the light-emitting element consisting only of the second quantum dot illustrated in FIG. 32. This relationship between voltage and current density is calculated based on an instance where a diode satisfying Jᵢ=J₀exp[−e(V_{d}−V₀)/(nkT)] (here, i is equal to one or two, V_{d} denotes voltage across the diode, J₀ and V₀ denote constants, e denotes elementary charge, n denotes diode coefficient and is equal to five, k denotes the Boltzmann constant, and T denotes temperature and is equal to 300 [K]), and a resistor having a constant resistance Rs (here, voltage across the resistor is given by V_{R}=Jᵢ×Rₛ) are connected in series. Here, the calculation with regard to the light-emitting element consisting only of the first quantum dot QD1 is made based on V₀=0, and the calculation with regard to the light-emitting element consisting only of the second quantum dot QD2 is made based on V₀=1 [V].

FIG. 34 is a graph showing the relationship between luminance [cd/m²], and the driving voltage [V] of the light-emitting element consisting only of the first quantum dot QD1 illustrated in FIG. 32 as well as the driving voltage [V] of the light-emitting element consisting only of the second quantum dot QD2 illustrated in FIG. 32. Here, the luminance is proportional to the density Jᵢ of current flowing through each element; in addition, with regard to emission efficiency, which is used as a coefficient for converting the current density Jᵢ into luminance, 30 [cd/A] is set for the light-emitting element consisting only of the first quantum dot QD1, and 15 [cd/A] is set for the light-emitting element consisting only of the second quantum dot QD2.

As shown in FIGS. 33 and 34, the turn-on voltage of the light-emitting element consisting only of the second quantum dot QD2 stands at about 3.2 [V]. On the other hand, the turn-on voltage of the light-emitting element consisting only of the first quantum dot QD1 stands at about 2.2 [V]. Their turn-on voltage difference is produced by the foregoing settings, in which the constant V₀ in the light-emitting element consisting only of the first quantum dot QD1 stands at 0, and in which the constant V₀ in the light-emitting element consisting only of the second quantum dot QD2 stands at 1 [V]. The difference in V₀ reveals that the first quantum dot QD1 includes a thicker middle layer, which is the first middle layer t1, than the second quantum dot QD2, thereby facilitating current injection into the core c1 of the first quantum dot QD1.

FIG. 35 is a graph showing the relationship between luminance [cd/m²], and the current densities [mA/cm²] of the light-emitting element consisting only of the first quantum dot illustrated in FIG. 32, of the light-emitting element consisting only of the second quantum dot illustrated in FIG. 32, and of the light-emitting element 1 according to this example. The relationship between current density and luminance in the light-emitting element 1 is calculated from the relationship between the driving voltage, current density, and luminance of each of the first quantum dot QD1 and second quantum dot QD2. The respective inclined lines in FIG. 35 indicates the emission efficiency of the light-emitting element consisting only of the first quantum dot QD1, the emission efficiency of the light-emitting element consisting only of the second quantum dot QD2, and the emission efficiency of the light-emitting element 1.

At a small current density, the emission efficiency of the light-emitting element 1 is small, like the emission efficiency of the first quantum dot QD1. On other hand, the emission efficiency of the light-emitting element 1 increases gradually along with increase in the current density. As such, the emission efficiency of the light-emitting element 1 according to the present disclosure is small at a small driving voltage or a small driving current. The emission efficiency is small, thus producing a small degree of variability in the emission intensity of the light-emitting element 1 even when the driving voltage or the drive current varies. At the same time, the emission efficiency of the light-emitting element 1 according to the present disclosure is large at a large driving voltage or a large driving current. The emission efficiency is large, thus enabling increase in the maximum emission intensity of the light-emitting element 1, or decrease in the current consumption of the light-emitting element 1.

### Example 2

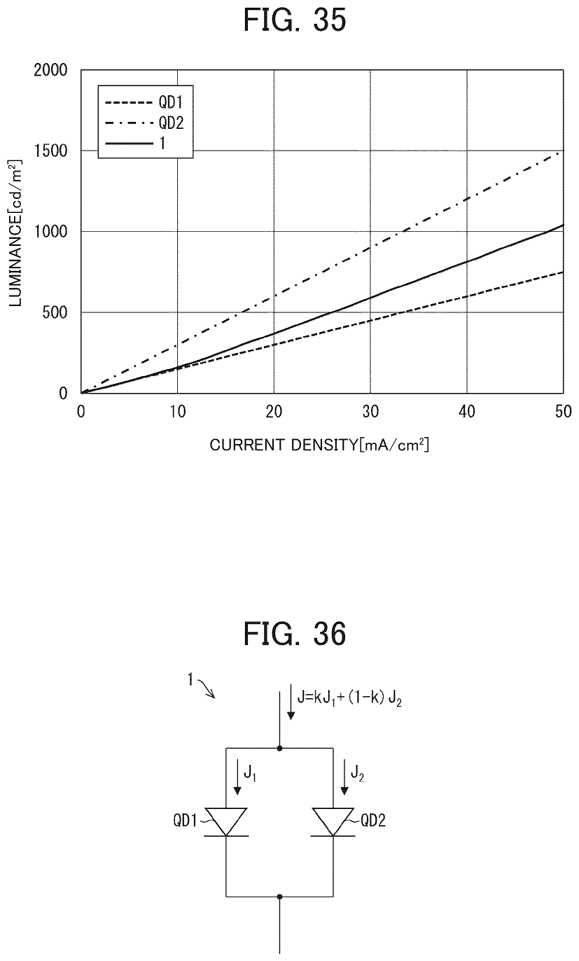

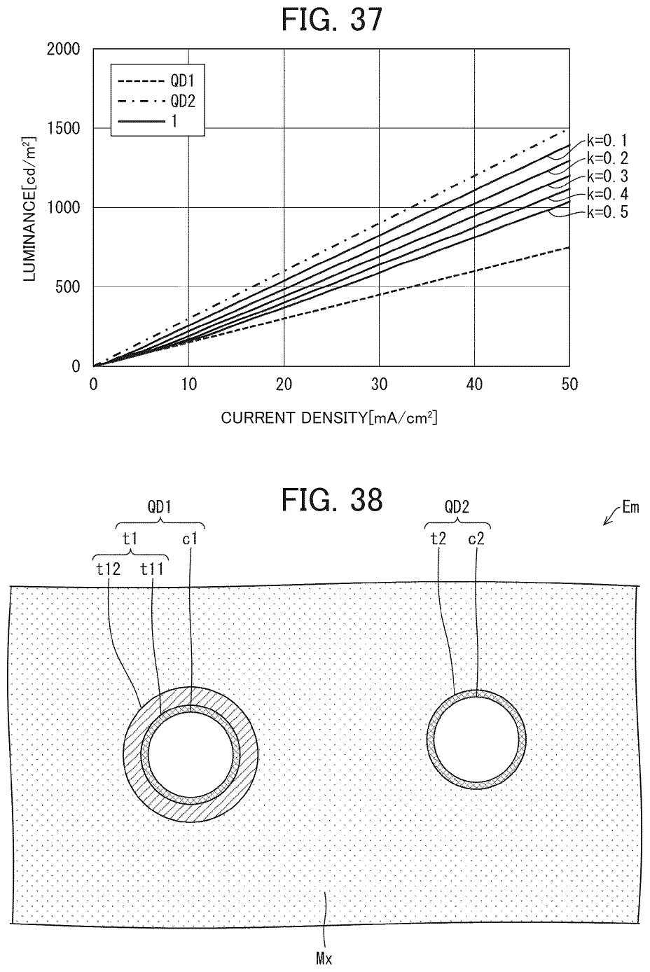

Another example of the present disclosure will be described below. FIG. 36 is a schematic circuit diagram of the light-emitting element 1 according to this example. FIG. 37 is a graph showing the relationship between luminance [cd/m²], and the current densities [mA/cm²] of a light-emitting element consisting only of the first quantum dot QD1 illustrated in FIG. 36, of a light-emitting element consisting only of the second quantum dot QD2 illustrated in FIG. 36, and of the light-emitting element 1 according to this example. FIGS. 36 and 37 show simulations conducted in each of k=0.1, k=0.2, k=0.3, k=0.4, and k=0.5, where the ratio of the first quantum dot QD1 and second quantum dot QD2 stands at k: (k−1). The others are similar to those in Example 1.

FIG. 37 reveals that the range in which the light-emitting element 1 exhibits small emission efficiency is wider as the ratio of the first quantum dot QD1 is larger. On the other hand, the light-emitting element 1 exhibits smaller emission efficiency at a large current density as the ratio of the first quantum dot QD1 is larger. Accordingly, 0.1<k<0.5 may be satisfied, and 0.3<k<0.5 may be satisfied.

### Ninth Embodiment

Another embodiment of the present disclosure will be described. It is noted that for convenience in description, components having the same functions as those of the components described in the foregoing embodiments will be denoted by the same signs, and that their descriptions will not be repeated.

FIG. 38 is a cross-sectional view of an example of the configuration of the emission layer according to one embodiment of the present disclosure. As illustrated in FIG. 38, the first middle layer t1 of the first quantum dot QD1 includes an inner layer t11 adjacent to the core c1, and an outer layer t12 adjacent to the inorganic matrix member Mx. The inner layer t11 and the second middle layer t2 may have an equal thickness. The material of the inner layer t11 and the material of the second middle layer t2 may be identical.

The material of the first middle layer t1 may be selected in such a manner that the lattice constant of the inner layer t11 is a value between the lattice constant of the core c1 and the lattice constant of the outer layer t12. This reduces the mismatch in lattice constant between the core c1 and the outer layer t12, thereby enabling reduction of lattice defects in the first quantum dot QD1. This lattice defect reduction can improve the emission efficiency of the first quantum dot QD1.

### Modification

This embodiment is not limited to the configuration example illustrated in FIG. 38. For example, the first middle layer t1 may include three or more layers. For example, the second middle layer t2 may include two or more layers.

### Tenth Embodiment

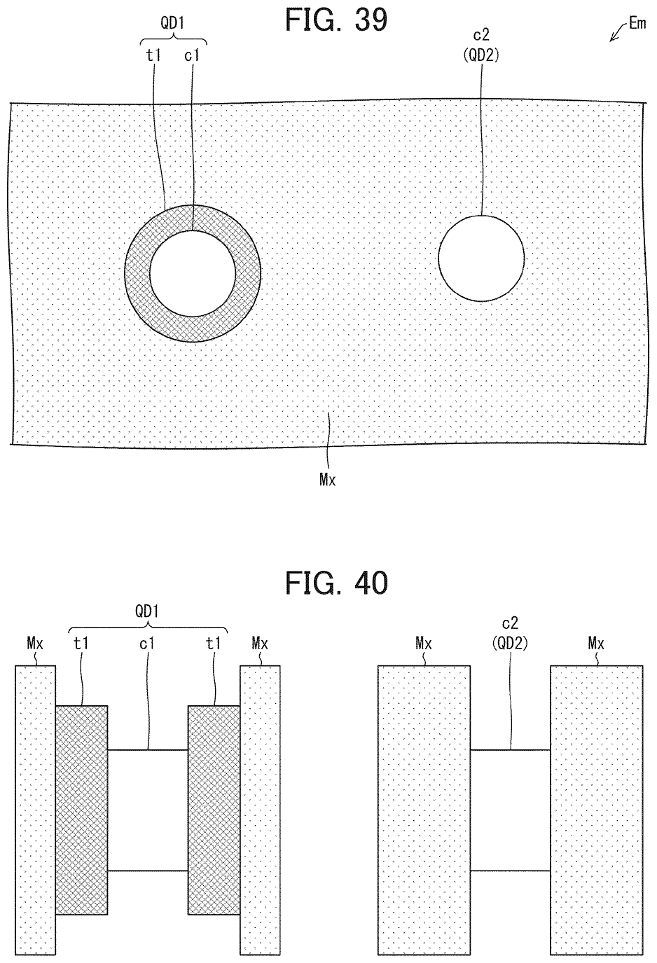

FIG. 39 is a cross-sectional view of an example of the configuration of the emission layer according to one embodiment of the present disclosure. As illustrated in FIG. 39, the first middle layer t1 containing a material different from the core material and matrix material may be positioned between the core c1 of the first quantum dot QD1 and the inorganic matrix member Mx. The core c2 of the second quantum dot QD2 may be in direct contact with the inorganic matrix member Mx. The first middle layer t1 may have a thickness of 0.63 [nm] or greater.

The first middle layer t1 may be the shell of the first quantum dot QD1. In other words, the first quantum dot QD1 may be a core-shell type, and the second quantum dot QD2 may be a shell-less type having a core only. The surface of the second quantum dot QD2 is protected by the inorganic matrix member Mx. Thus, the second quantum dot QD2 and its core c2 are less likely to deteriorate even when the second quantum dot QD2 is a shell-less type.

FIG. 40 illustrates an example of the energy band structure of the first and second quantum dots illustrated in FIG. 39, and of the nearby inorganic matrix member. As illustrated in FIG. 40, the second quantum dot QD2 is a shell-less type, and the first quantum dot QD1 is a core-shell type. That is, the effective thickness of the inorganic matrix member Mx in the first quantum dot is smaller than that of the inorganic matrix member Mx in the second quantum dot. Hence, the first quantum dot QD1 is more likely to undergo current injection and has a smaller quantum confinement effect than the second quantum dot QD2.

### Modification

The configuration according to the tenth embodiment can be combined with the foregoing configuration according to the ninth embodiment. For example, the first middle layer t1 may include two or more layers, and the second quantum dot QD2 may be a shell-less type.

### Eleventh Embodiment

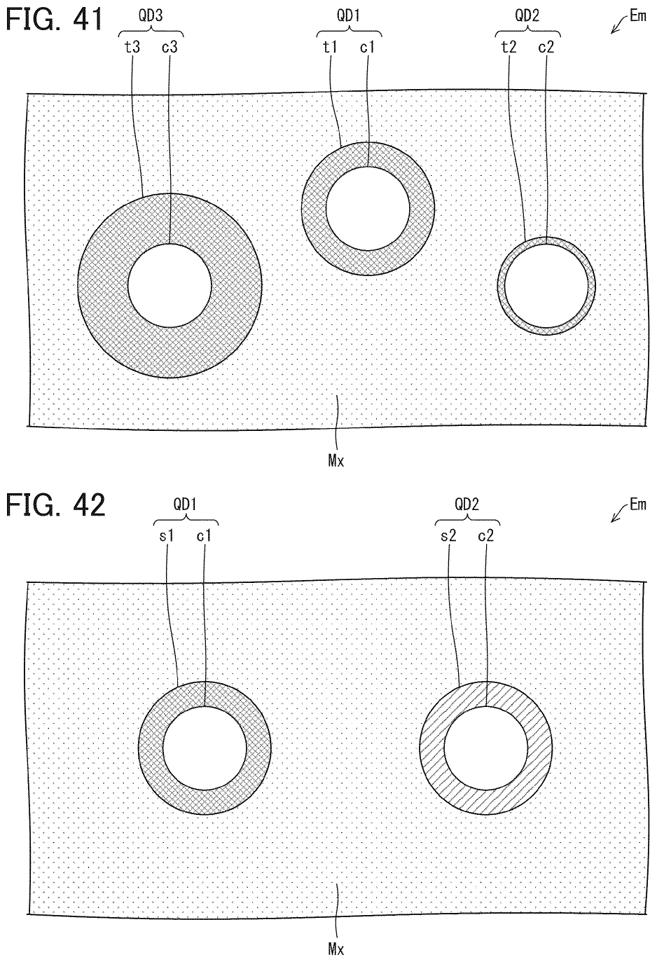

FIG. 41 is a cross-sectional view of an example of the configuration of the emission layer according to one embodiment of the present disclosure. As illustrated in FIG. 41, the emission layer Em may further include a third quantum dot QD3. The third quantum dot QD3 emits light of the same color as the first quantum dot QD1, and has a larger particle diameter than the first quantum dot by 1.26 [nm] or greater. The particle diameter of a core c3 of the third quantum dot QD3 may be equal to the particle diameter of the core c1 of the first quantum dot QD1, and the material of the core c3 of the third quantum dot QD3 may be the same as the material of the core c1 of the first quantum dot QD1.

A third middle layer t3 containing a material different from the core material and matrix material may be positioned between the core c3 of the third quantum dot QD3 and the inorganic matrix member Mx. The third middle layer t3 may be thicker than the first middle layer t1 by 0.63 [nm] or greater. The band gap of the third middle layer t3 may be larger than the band gap of the core c3 of the third quantum dot QD3, and smaller than the band gap of the inorganic matrix member Mx. The third middle layer t3 may be made of the same material as the first middle layer t1.

### Modification

The configuration according to the eleventh embodiment can be combined with the foregoing configurations according to the ninth to tenth embodiments. For example, the second quantum dot QD2 may be a shell-less type. For example, the third middle layer t3 of the third quantum dot QD3 may include two or more layers. For example, the first middle layer t1 of the first quantum dot QD1 may include two or more layers.

### Twelfth Embodiment

FIG. 42 is a cross-sectional view of an example of the configuration of the emission layer according to one embodiment of the present disclosure. As illustrated in FIG. 42, the particle diameter of the second quantum dot QD2 according to this embodiment may be equal to the particle diameter of the first quantum dot QD1. The second quantum dot QD2 according to this embodiment emits light of the same color as the first quantum dot QD1, and has a surface band gap larger than the surface band gap of the first quantum dot QD1.

A first shell s1 containing a material different from the core material and matrix material may be positioned between the core c1 of the first quantum dot QD1 and the inorganic matrix member Mx. A second shell s2 containing a material different from the core material and matrix material may be positioned between the core c2 of the second quantum dot QD2 and the inorganic matrix member Mx. The band gap of the second shell s2 may be larger than the band gap of the first shell s1. The second shell s2 may contain a material different from that of the first shell s1.

The band gap of the first shell s1 may be larger than the band gap of the core c1 of the first quantum dot QD1, and smaller than the band gap of the inorganic matrix member Mx. The band gap of the second shell s2 may be larger than the band gap of the core c2 of the second quantum dot QD2, and smaller than the band gap of the inorganic matrix member Mx.

In the present disclosure, the thickness of the first shell s1 may be calculated by dividing, by two, the difference between the particle diameter of the first quantum dot QD1 and the particle diameter of the core c1 of the first quantum dot QD1. Likewise, the thickness of the second shell s2 may be calculated by dividing, by two, the difference between the particle diameter of the second quantum dot QD2 and the particle diameter of the core c2 of the second quantum dot QD2.

The material of the first shell s1, the material of the second shell s2, and the matrix material may contain one or more common elements. These common elements may include at least one of zinc (Zn), sulfur(S), and selenium (Se). The core material of the cores c1 and c2, the material of the first shell s1, the material of the second shell s2, and the matrix material of the inorganic matrix member Mx may be combined based on any combination shown in Table 4 below. It is to be understood that the composition ratios of the respective materials may differ from stoichiometric composition ratios (stoichiometry) except for those specified in the table (ZnSe₁₋ₓSₓ, ZnSe_{1-y}S_{y}, and ZnSe_{1-z}S_{z} in Table 4), and that each material may include a doped material or an impurity.

TABLE 4

| | | | Inorganic Matrix |
|---|---|---|---|
| Core | First Shell | Second Shell | Member |
| InP | ZnSe | ZnSeS | ZnS |
| ZnSe | ZnSe₁₋ₓSₓ | ZnSe_{1-y}S_{y} | ZnS |
| ZnSeTe | ZnSe | ZnSeS | ZnS |
| CdSe | ZnSe | ZnSeS | ZnS |
| CdSe | CdS | ZnSe | ZnS |
| InP | ZnSe | ZnSe₁₋ₓSₓ | ZnSe_{1-y}S_{y} |
| ZnSe | ZnSe₁₋ₓSₓ | ZnSe_{1-y}S_{y} | ZnSe_{1-z}S_{z} |
| ZnSeTe | ZnSe | ZnSe₁₋ₓSₓ | ZnSe_{1-y}S_{y} |
| CdSe | ZnSe | ZnSe₁₋ₓSₓ | ZnSe_{1-y}S_{y} |

In the foregoing, 0 < x < y < z < 1

### Quantum Confinement Effect

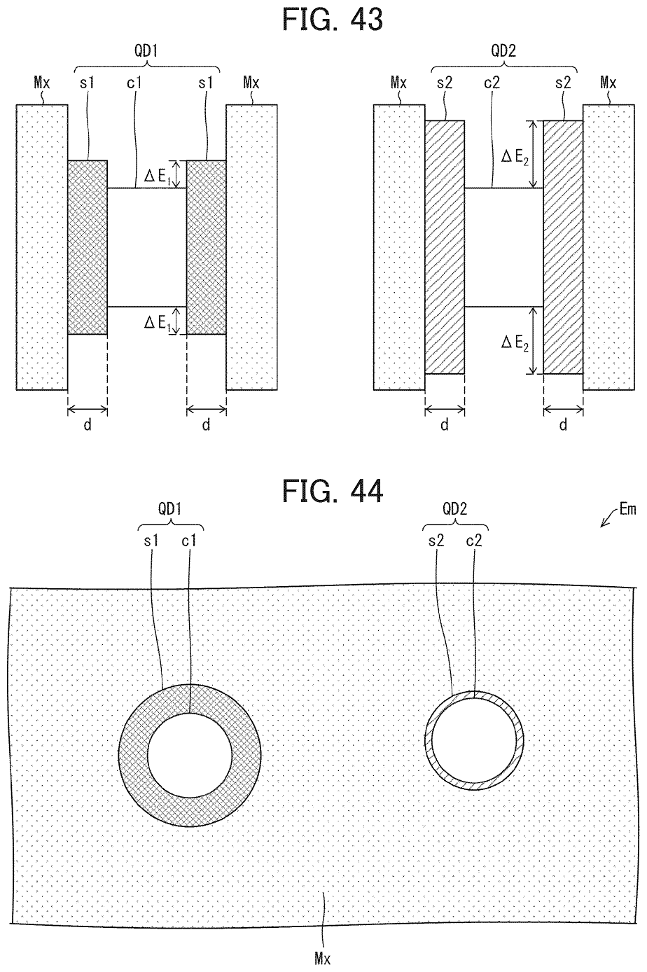

FIG. 43 illustrates an example of the energy band structure of the first and second quantum dots illustrated in FIG. 42, and of the nearby inorganic matrix member. As shown in FIG. 43, the band gap of the first shell s1 is smaller than the band gap of the second shell s2. Hence, the first quantum dot QD1 is more likely to undergo current injection and has a smaller quantum confinement effect than the second quantum dot QD2. That is, the first quantum dot QD1 has a smaller turn-on voltage, and a smaller upper limit of emission efficiency.

In the example illustrated in FIG. 43, an energy difference ΔE₁ [eV] between the highest occupied molecular orbital (HOMO) of the core c1 of the first quantum dot QD1 and the HOMO of the first shell s1 is equal to an energy difference ΔE₁ [eV] between the lowest unoccupied molecular orbital (LUMO) of the core c1 of the first quantum dot QD1 and the LUMO of the first shell s1. Also, in the second quantum dot QD2, an energy difference ΔE₂ between the HOMOs is equal to an energy difference ΔE₂ between the LUMOs. Further, the energy difference ΔE₁ in the first quantum dot QD1 is smaller than the energy difference ΔE₂ in the second quantum dot QD2 (ΔE₁<ΔE₂).

### Modification

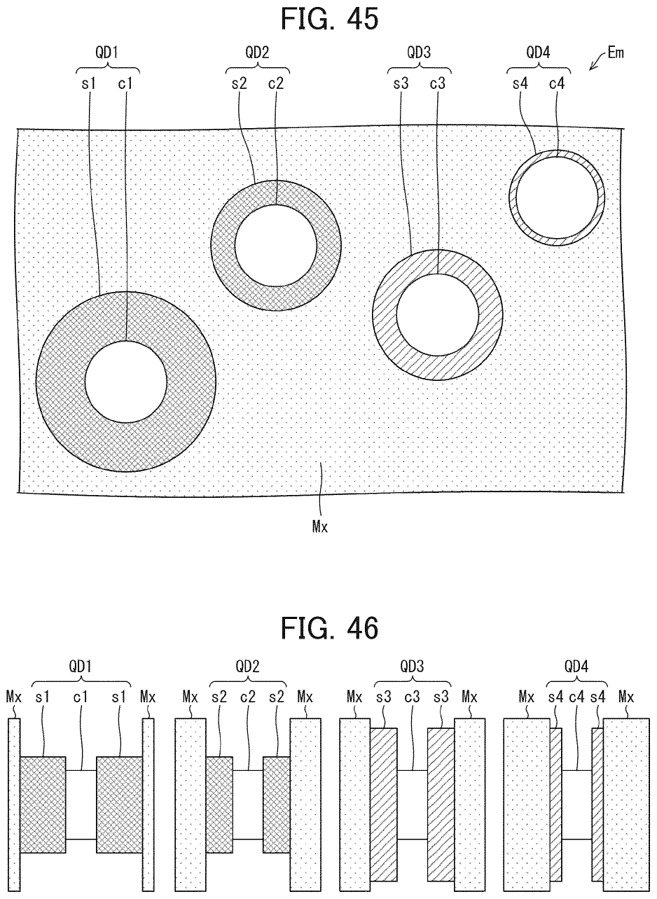

FIGS. 44 and 45 are cross-sectional views of modifications of the configuration of the emission layer according to the embodiment of the present disclosure. The configuration according to the twelfth embodiment can be combined with the foregoing configurations according to the eighth to eleventh embodiments. As illustrated in FIG. 44 for instance, the second shell s2 may be thinner than the first shell s1. For example, the second quantum dot QD2 may be a shell-less type. For example, the first shell s1 may include two or more layers. For example, the second shell s2 may include two or more layers.

As illustrated in FIG. 45 for instance, the emission layer Em may include the first quantum dot QD1, the second quantum dot QD2, the third quantum dot QD3, and a fourth quantum dot QD4 that emit light of the same color. The core c1 of the first quantum dot QD1, the core c2 of the second quantum dot QD2, the core c3 of the third quantum dot QD3, and a core c4 of the fourth quantum dot QD4 may be made of the same material, and the cores c1, c2, c3, and c4 may have an equal particle diameter. The particle diameter of the first quantum dot QD1 may be larger than the particle diameter of the second quantum dot QD2; in addition, the particle diameter of the second quantum dot QD2 may be equal to the particle diameter of the third quantum dot QD3; in addition, the particle diameter of the third quantum dot QD3 may be larger than the particle diameter of the fourth quantum dot QD4. The first shell s1 and the second shell s2 may be made of the same material; in addition, a third shell s3 and a fourth shell s4 may be made of the same material; in addition, the band gap of the third shell s3 may be larger than the band gap of the second shell s2.

FIG. 46 illustrates an example of the energy band structure of the first, second, third, and fourth quantum dots illustrated in FIG. 45, and of the nearby inorganic matrix member. The proportion of a material having a small band gap gradually decreases near the cores c1, c2, c3, and c4 of the respective first quantum dot QD1, second quantum dot QD2, third quantum dot QD3, and fourth quantum dot QD4, from the left to right sides of FIG. 46. The smaller the proportion of the material having a small band gap is near the core, the less the core is likely to undergo current injection, thus providing the core with a larger quantum confinement effect.

Here, the “material having a small band gap” is a material having a smaller band gap than the inorganic matrix member Mx. To be specific, such materials are the first shell s1 of the first quantum dot QD1, the second shell s2 of the second quantum dot QD2, the third shell s3 of the third quantum dot QD3, and the fourth shell s4 of the fourth quantum dot QD4.

### Thirteenth Embodiment

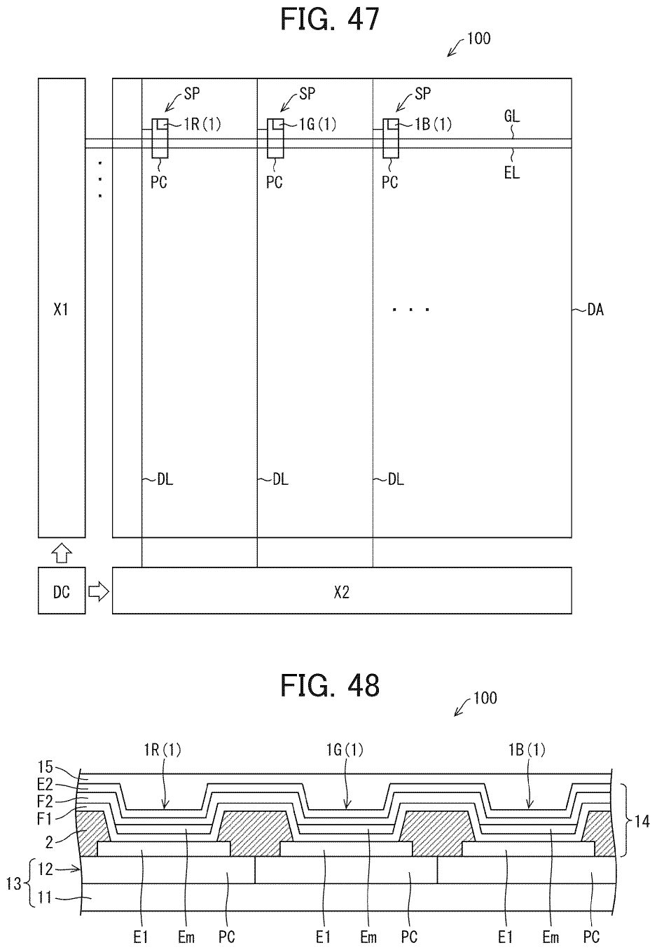

FIG. 47 is a schematic diagram illustrating an example of the configuration of a display device according to one embodiment of the present disclosure. FIG. 48 is a cross-sectional view of an example of the configuration of the display device according to the embodiment of the present disclosure. As illustrated in FIG. 47, a display device 100 is provided with the following: a display unit DA including a plurality of subpixels SP; a first driver X1 and a second driver X2 that drive the plurality of subpixels SP; and a display control unit DC that controls the first driver X1 and the second driver X2. The subpixel SP includes the light-emitting element 1, and a pixel circuit PC connected to a light-emitting element 1. The pixel circuit PC may be connected to a scanning signal line GL, a data signal line DL, and an emission control line EL. The scanning signal line GL and the emission control line EL may be connected to the first driver X1, and the data signal line DL may be connected to the second driver X2.

As illustrated in FIG. 48, the display device 100 may include the following: a pixel circuit board 13 including a substrate 11 and a pixel circuit layer 12; a light-emitting element layer 14; and a sealing layer 15. The substrate 11 can be a glass substrate, a resin substrate, or other kinds of substrate. The substrate 11 may be flexible. The pixel circuit layer 12 includes a plurality of pixel circuits PC arranged in matrix for instance. The pixel circuit PC may include the following: a pixel capacitor in which a grayscale signal is written; a transistor that controls the current value of the light-emitting element 1 in accordance with the grayscale signal; a transistor connected to the scanning signal line GL and the data signal line DL; and a transistor connected to the emission control line EL.

The light-emitting element layer 14 may include, sequentially on the pixel circuit board 13, the anode E1, an edge cover film 2 covering the edge of the anode E1, the first functional layer F1, the emission layer Em, the second functional layer F2, and the cathode E2.

The edge cover film 2 is an insulating layer having a visible-light absorbing property or a light blocking property. An example of the material of the edge cover film 2 is photosensitive resins containing a light-absorptive agent, such as carbon black. The photosensitive resins include organic photosensitive insulating materials, such as polyimide and acrylic resin.

The light-emitting element layer 14 may be provided with the following: a light-emitting element 1R including an emission layer Em(R) that emits red light; a light-emitting element 1G including an emission layer Em(G) that emits green light; and a light-emitting element 1B including an emission layer Em(B) that emits blue light. The sealing layer 15 includes an inorganic insulating film, such as a silicon nitride film or a silicon oxide film, and avoids foreign matters (e.g., water and oxygen) from entering the light-emitting element layer 14.

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure. Furthermore, combining the technical means disclosed in the respective embodiments can form a new technical feature.

1. A light-emitting element comprising:
an anode;
a cathode; and
an emission layer positioned between the anode and the cathode,
wherein the emission layer includes a first quantum dot and a second quantum dot, the first quantum dot includes a first core, a shell being in contact with the first core, and a first layer formed outside the shell and formed from a first material, and
the second quantum dot includes a second core, and a second layer being in contact with the second core and formed from a second material,
wherein the first layer is a non-covering type being in contact with a part of the shell.

2-9. (canceled)

10. The light-emitting element according to claim 1, wherein the second layer is a covering type covering a whole of the second core.

11. (canceled)

12. (canceled)

13. The light-emitting element according to claim 1, wherein
the second quantum dot includes a third layer being in contact with the second layer, and formed as a non-covering type containing a same material as the first material, and
an occupancy rate of the first layer on a surface of the shell is larger than an occupancy rate of the third layer on a surface of the second layer.

14. (canceled)

15. (canceled)

16. The light-emitting element according to claim 1, wherein the first material is silicon oxide.

17. The light-emitting element according to claim 1, wherein the emission layer includes an organic ligand member positioned between the first quantum dot and the second quantum dot.

18. The light-emitting element according to claim 17, wherein the organic ligand member includes an organic ligand member being in contact with the first layer, and an organic ligand member being in contact with the second layer.

19. The light-emitting element according to claim 1, wherein the emission layer includes an inorganic matrix member between the first quantum dot and the second quantum dot.

20. The light-emitting element according to claim 19, wherein the inorganic matrix member is in contact with the first layer and the second layer.

21. The light-emitting element according to claim 19, wherein
the inorganic matrix member is formed from silicon oxide.

22. (canceled)

23. A display device comprising the light-emitting element according to claim 1.

24. A light-emitting element comprising:
an anode;
a cathode; and
an emission layer positioned between the anode and the cathode,
wherein the emission layer includes a first quantum dot and a second quantum dot,
the first quantum dot includes a first core, a shell being in contact with the first core, and a first layer formed outside the shell and formed from a first material, and
the second quantum dot includes a second core, and a second layer being in contact with the second core and formed from a second material, wherein
the first layer is a covering type covering a whole of the shell,
the second quantum dot includes a third layer being in contact with the second layer, and formed as a non-covering type containing a same material as the first material.

25. The light-emitting element according to claim 24, wherein the first material is silicon oxide.

26. The light-emitting element according to claim 24, wherein the emission layer includes an organic ligand member positioned between the first quantum dot and the second quantum dot.

27. The light-emitting element according to claim 24, wherein the emission layer includes an inorganic matrix member between the first quantum dot and the second quantum dot.

28. The light-emitting element according to claim 27, wherein the inorganic matrix member is in contact with the first layer and the second layer.

29. A light-emitting element comprising:
an anode;
a cathode; and
an emission layer positioned between the anode and the cathode,
wherein the emission layer includes a first quantum dot and a second quantum dot,
the first quantum dot includes a first core, a shell being in contact with the first core, and a first layer formed outside the shell and formed from a first material, and
the second quantum dot includes a second core, and a second layer being in contact with the second core and formed from a second material, wherein
the first layer is a covering type covering a whole of the shell,
the second quantum dot includes a third layer being in contact with the second layer, and formed as a covering type containing a same material as the first material, and
an average thickness of the third layer is smaller than an average thickness of the first layer.

30. The light-emitting element according to claim 29, wherein the first material is silicon oxide.

31. The light-emitting element according to claim 29, wherein the emission layer includes an organic ligand member positioned between the first quantum dot and the second quantum dot.

32. The light-emitting element according to claim 29, wherein the emission layer includes an inorganic matrix member between the first quantum dot and the second quantum dot.

33. The light-emitting element according to claim 32, wherein the inorganic matrix member is in contact with the first layer and the second layer.
